(19) United States
(12) Patent Application Publication
(10) Pub. No.: US 2024/0005991 A1
(43) Pub. Date: Jan. 4, 2024

(54) SEMICONDUCTOR STORAGE DEVICE

(71) Applicant: Kioxia Corporation, Tokyo (JP)

(72) Inventor: Ryota SUZUKI, Yokkaichi (JP)

(73) Assignee: Kioxia Corporation, Tokyo (JP)

(21) Appl. No.: 18/336,388

(22) Filed: Jun. 16, 2023

(30) Foreign Application Priority Data
Jun. 29, 2022 (JP) 2022-104434

(51) Int. Cl. G11C 16/04; G11C 16/14; H10B 43/10; H10B 43/27; H10B 43/35; H10B 41/10; H10B 41/27; H10B 41/35

(52) U.S. Cl. CPC G11C 16/0483; G11C 16/14; H10B 43/10; H10B 43/27; H10B 43/35; H10B 41/10; H10B 41/27; H10B 41/35

(57) ABSTRACT

A semiconductor storage device according to an embodiment includes a first multi-layered body, a second multi-layered body, a first columnar part, a second columnar part, an electrode part, and an impurity-diffusion region. The second multi-layered body is above the first multi-layered body. The first columnar part is in the first multi-layered body. The first columnar part includes a first semiconductor layer. The second columnar part is in the second multi-layered body. The second columnar part includes a second semiconductor layer. The electrode part is inside at least one of the upper end of the first columnar part and the lower end of the second columnar part. The impurity-diffusion region protrudes from the end surface of the electrode part toward the inside of the first semiconductor layer in the first direction.

### CROSS-REFERENCE TO RELATED APPLICATION

This application is based upon and claims the benefit of priority from Japanese Patent Application No. 2022-104434, filed Jun. 29, 2022; the entire contents of which are incorporated herein by reference.

### FIELD

Embodiments described herein relate generally to a semiconductor storage device.

### BACKGROUND ART

A NAND type flash memory having memory cells three-dimensionally stacked in layers is known.

### BRIEF DESCRIPTION OF THE DRAWINGS

FIG. 1 is a block diagram showing a configuration of a semiconductor storage device according to a first embodiment.

FIG. 2 is a view explaining a threshold voltage profile of a memory cell according to the first embodiment.

FIG. 3 is a perspective view showing the semiconductor storage device according to the first embodiment.

FIG. 4 is a cross-sectional view showing a part of a memory cell array according to the first embodiment when viewed from above.

FIG. 5 is a view showing a circuit configuration included in a memory cell array according to the first embodiment.

FIG. 6 is a cross-sectional view showing a part of the semiconductor storage device according to the first embodiment.

FIG. 7 is a cross-sectional view showing a columnar part of the semiconductor storage device according to the first embodiment.

FIG. 8 is a cross-sectional view showing a part of the semiconductor storage device according to the first embodiment.

FIG. 9 is an enlarged cross-sectional view showing a region close to an electrode part of the semiconductor storage device according to the first embodiment.

FIG. 10 is a timing chart showing a voltage of each of wirings when applying an erasing pulse in a block erase operation.

FIG. 11 is a cross-sectional view explaining an operation of the semiconductor storage device according to the first embodiment.

FIG. 12 is a cross-sectional view explaining an operation of the semiconductor storage device according to the first embodiment.

FIG. 13 is a cross-sectional view explaining an operation of the semiconductor storage device according to the first embodiment.

FIG. 14 is a cross-sectional view explaining a method of manufacturing the semiconductor storage device according to the first embodiment.

FIG. 15 is a cross-sectional view explaining a method of manufacturing the semiconductor storage device according to the first embodiment.

FIG. 16 is a cross-sectional view explaining a method of manufacturing the semiconductor storage device according to the first embodiment.

FIG. 17 is a cross-sectional view explaining a method of manufacturing the semiconductor storage device according to the first embodiment.

FIG. 18 is a cross-sectional view explaining a method of manufacturing the semiconductor storage device according to the first embodiment.

FIG. 19 is a cross-sectional view explaining a method of manufacturing the semiconductor storage device according to the first embodiment.

FIG. 20 is a cross-sectional view explaining a method of manufacturing the semiconductor storage device according to the first embodiment.

FIG. 21 is an enlarged cross-sectional view showing a region close to an electrode part of a semiconductor storage device according to a second embodiment.

FIG. 22 is a cross-sectional view explaining an operation of the semiconductor storage device according to the second embodiment.

FIG. 23 is a cross-sectional view explaining a method of manufacturing the semiconductor storage device according to the second embodiment.

FIG. 24 is a cross-sectional view explaining a method of manufacturing the semiconductor storage device according to the second embodiment.

FIG. 25 is a cross-sectional view explaining a method of manufacturing the semiconductor storage device according to the second embodiment.

FIG. 26 is a cross-sectional view explaining a method of manufacturing the semiconductor storage device according to the second embodiment.

FIG. 27 is a cross-sectional view explaining a method of manufacturing the semiconductor storage device according to the second embodiment.

FIG. 28 is a cross-sectional view explaining a method of manufacturing the semiconductor storage device according to the second embodiment.

FIG. 29 is a cross-sectional view explaining a method of manufacturing the semiconductor storage device according to the second embodiment.

### DETAILED DESCRIPTION

A semiconductor storage device according to an embodiment includes a first multi-layered body, a second multi-layered body, a first columnar part, a second columnar part, an electrode part, and an impurity-diffusion region. The first multi-layered body includes a plurality of first conductive layers. The first conductive layers are stacked in layers in a first direction. The first conductive layers are electrically isolated from each other. The second multi-layered body is above the first multi-layered body. The second multi-layered includes a plurality of second conductive layers. The second conductive layers are stacked in layers in the first direction. The second conductive layers are electrically isolated from each other. The first columnar part is in the first multi-layered body so as to extend in the first direction. The first columnar part includes a first charge storage film and a first semiconductor layer. The first columnar part has an upper end. The second columnar part is in the second multi-layered body so as to extend in the first direction. The second columnar part includes a second charge storage film and a second semiconductor layer. The second columnar part has a lower end. The electrode part is inside at least one of the upper end of the first columnar part and the lower end of the second columnar part. The electrode part has an end surface. The impurity-diffusion region protrudes from the end surface of the electrode part toward the inside of the first semiconductor layer in the first direction.

Hereinafter, a semiconductor storage device according to the embodiment will be described with reference to the drawings. In the following description, configurations having the same or similar functions will be designated by the same reference signs. Duplicate descriptions of such configurations may be omitted. The drawings are schematic or conceptual, and a relationship between a thickness and a width of each portion, ratios of sizes between portions, and the like are not necessarily the same as the reality. In this specification, the term “connect” is not limited to a case of physical connection, and also includes a case of electrical connection. That is, the term “connect” is not limited to a case where two members are directly in contact with each other, and also includes a case where another member is interposed between the two members. The term “face” is not limited to a case in which two members face each other without another member interposed therebetween, and also includes a case in which two members face each other with another member interposed therebetween. In this specification, the terms “parallel”, “perpendicular”, and “the same as” may also include “substantially parallel”, “substantially perpendicular”, and “substantially the same as”, respectively. In this specification, the term “extend(s) in an A direction” means that, for example, the length in the A direction is larger than the minimum length of lengths in the X direction, the Y direction, and the Z direction described below. Here, the term “A direction” is an optionally-selected direction.

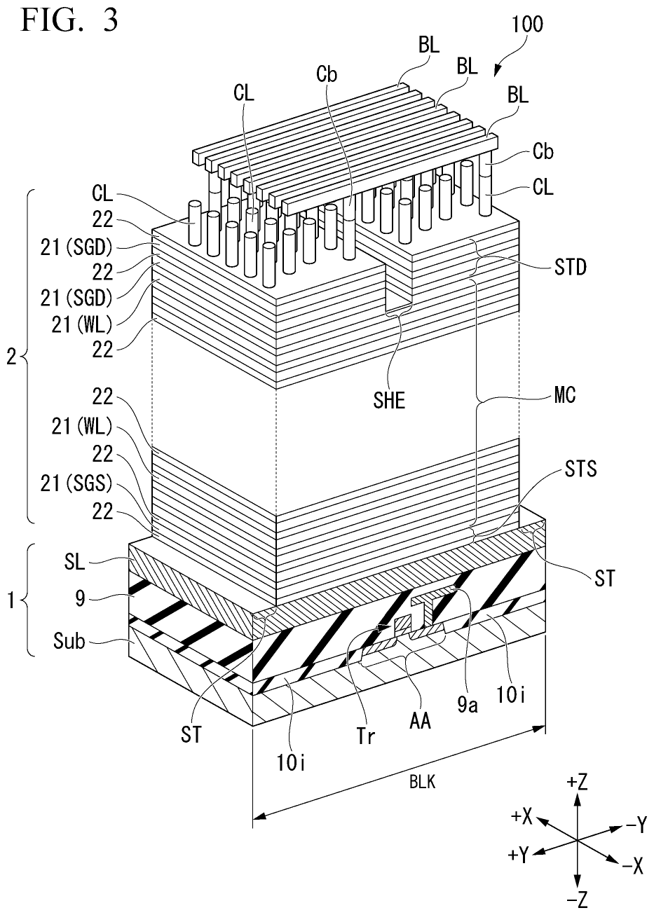

First, the +X direction, the −X direction, the +Y direction, the −Y direction, the +Z direction, and the −Z direction are defined as follows. Each of the +X direction, the −X direction, the +Y direction, and the −Y direction is the direction parallel to a surface (refer to FIG. 3) of a substrate Sub described below. The +X direction is one direction of the directions orthogonal to an extending direction of a word line WL described below (refer to FIG. 3). The −X direction is a direction opposite to the +X direction. The +X direction and the −X direction will be simply referred to as an “X direction” unless otherwise distinguished. The +Y direction and the −Y direction are directions crossing the X direction and are, for example, directions orthogonal to the X direction. The +Y direction is one direction of the directions in which the word line WL described below (refer to FIG. 3) extends. The −Y direction is a direction opposite to the +Y direction. The +Y direction and the −Y direction will be simply referred to as a “Y direction” unless otherwise distinguished. The +Z direction and the −Z direction are directions crossing the X direction and the Y direction and are, for example, directions orthogonal to the X direction and the Y direction. Each of the +Z direction and the −Z direction is a thickness direction of the substrate Sub (refer to FIG. 3). The +Z direction is a direction from the substrate Sub toward a multi-layered body 2 described below. The −Z direction is a direction opposite to the +Z direction. The +Z direction and the −Z direction will be simply referred to as a “Z direction” unless otherwise distinguished. In the specification, “the +Z direction” may be referred to as “upper”, “upward”, “above”, or the like, and “the −Z direction” may be referred to as “lower”, “downward”, “below”, or the like. However, this term is used for convenience of explanation but does not determine the direction of gravitational force. The +Z direction is an example of a “first direction”. The +Y direction is an example of a “second direction”. The +X direction is an example of a “third direction”.

In the drawings referred to below, hatching is appropriately added to some plan view configurations in order to make the drawing clearer. The hatching added to the plan view is not necessarily related to the material and the characteristics of a constituent element represented by the hatching. In each of a plan view and a cross-sectional view, a part of constituent elements such as a wiring, a contact, an interlayer insulating film, or the like is appropriately omitted in order to make a drawing clearer.

### First Embodiment

### <1. Configuration of Semiconductor Storage Device>

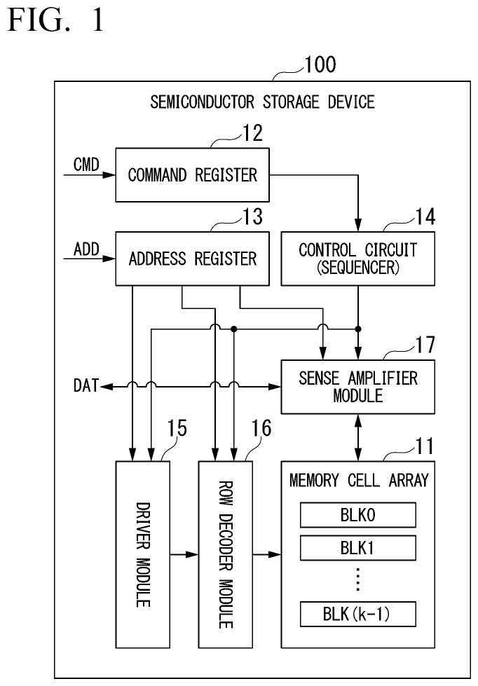

FIG. 1 is a block diagram showing a configuration of a semiconductor storage device 100 according to a first embodiment. The semiconductor storage device 100 is, for example, a nonvolatile semiconductor storage device. The semiconductor storage device 100 is a NAND type flash memory. The semiconductor storage device 100 can be connected to, for example, an external host device. The semiconductor storage device 100 is used as a storage space for the host device. The semiconductor storage device 100 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK, block BLK0 to BLK (k-1) (k is an integer greater than or equal to one). The block BLK is a collective body of a plurality of memory cell transistors. Each of the memory cell transistors is configured to store data non-volatilely. The block BLK is used as a data erase unit. A plurality of bit lines and a plurality of word lines are provided in the memory cell array 11. Each memory cell transistor is associated with one bit line and one word line.

The command register 12 stores a command CMD. The semiconductor storage device 100 receives the command CMD from the host device. The address register 13 stores address information ADD. The semiconductor storage device 100 receives the address information ADD from the host device. The control circuit 14 is a circuit configured to control various operations of the semiconductor storage device 100. For example, the control circuit 14 is configured to execute a data write operation, a data read operation, a data erase operation, or the like on the basis of the command CMD stored in the command register 12.

The driver module 15 includes a voltage generation circuit. The driver module is configured to generate voltages used in various operations of the semiconductor storage device 100. The various operations of the semiconductor storage device 100 are, for example, a write operation, a read operation, an erase operation, or the like. The driver module 15 supplies the generated voltage to the memory cell array 11, the row decoder module 16, and the sense amplifier module 17.

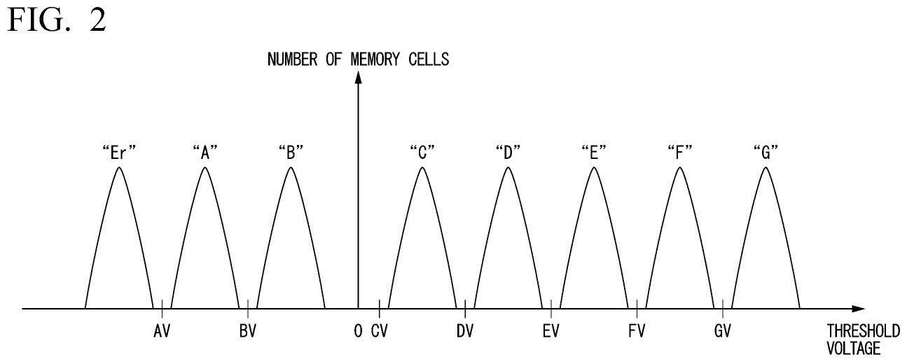

As shown in FIG. 2, the driver module 15 according to the embodiment can supply not only a positive voltage but also a negative voltage to the above members 11, 16, and 17.

FIG. 2 is a view explaining an example of a threshold voltage profile of a memory cell MC described below. Here, even where a plurality of memory cells MC hold the same data values as each other, the memory cells MC may have threshold voltages different from each other. Consequently, the threshold voltages of the plurality of the memory cells MC holding the same data values as each other form one profile referred to as a lob. In a case in which the memory cell MC is used in a triple level cell (TLC), the threshold value profile of the memory cell MC includes eight lobs. As shown in FIG. 2, each of the eight lobs is a voltage profile presenting the threshold voltage. In FIG. 2, the left side on the axis of abscissas represents the lower voltage side, and the right side on the axis of abscissas represents the higher voltage side. In the order from the lowest voltage profile to the highest voltage profile, the memory cells MC belonging to the eight lobs have an Er level, an A level, a B level, a C level, a D level, an E level, an F level, and a G level. For example, the Er level, the A level, the B level, the C level, the D level, the E level, the F level, and the G level mean the states of maintaining data “111”, data “011”, data “001”, data “101”, data “100”, data “000”, data “010”, and data “110”, respectively. The A level and the B level are in a region in which the threshold voltage is on the negative. The Er level corresponds to an erasing state.

The row decoder module 16 transfers a voltage applied to a signal line corresponding to a selected word line to the selected word line. The sense amplifier module 17 applies a desired voltage to each bit line in the write operation. In the read operation, the sense amplifier module 17 determines a data value stored in each memory cell transistor on the basis of a voltage of each bit line, and the sense amplifier module 17 transfers the determination result as read data DAT to the host device.

Next, a physical configuration of the semiconductor storage device 100 according to the first embodiment will be described.

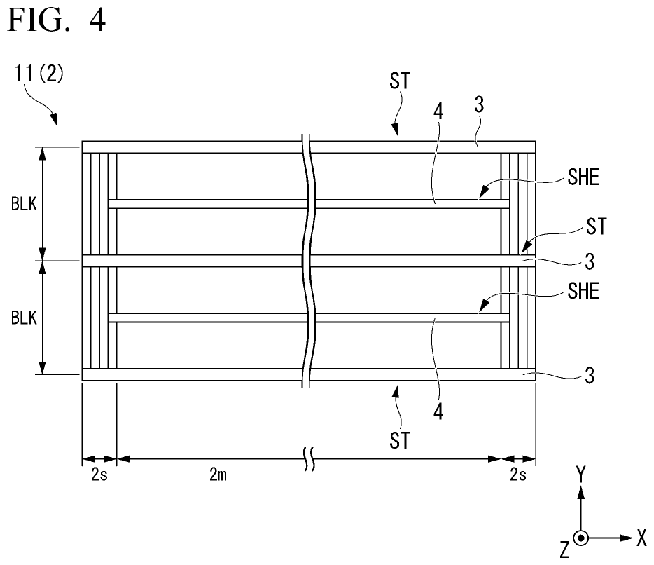

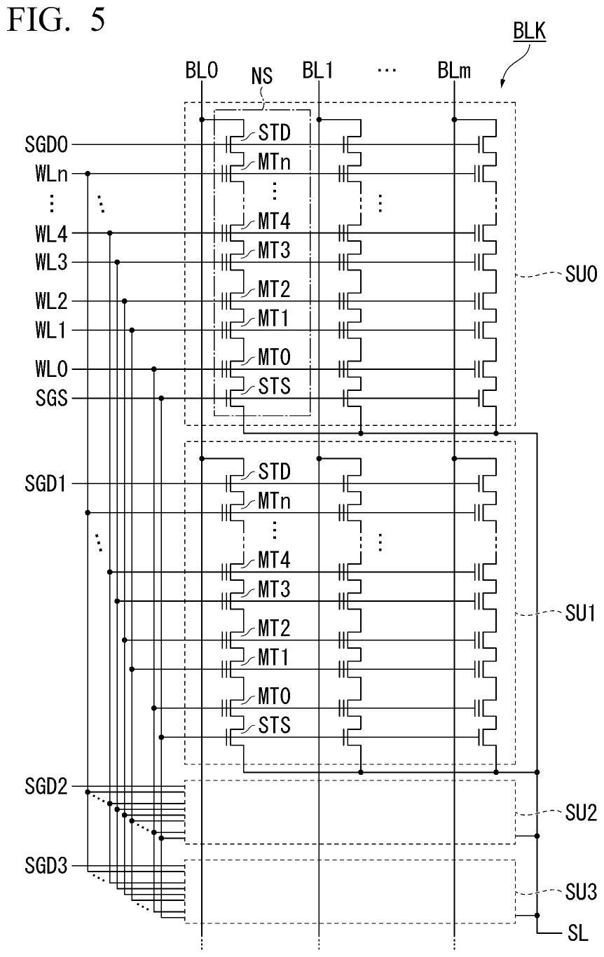

FIG. 3 is a perspective view showing the semiconductor storage device 100 according to the first embodiment. FIG. 4 is a cross-sectional view showing a part of the memory cell array 11 when viewed from above. FIG. 5 is a plan view showing the semiconductor storage device 100 according to the first embodiment. As shown in FIG. 3, the semiconductor storage device 100 according to the first embodiment is a non-volatile memory including memory cells each having a three-dimensional configuration.

The semiconductor storage device 100 includes a base body 1, the multi-layered body 2, a plurality of deep slits ST (a tabular part 3 shown in FIG. 4), a plurality of shallow slits SHE (a tabular part 4 shown in FIG. 4), and a plurality of columnar parts L.

The base body 1 includes a substrate Sub, an interlayer insulating film 9, and a source layer SL. The interlayer insulating film 9 is provided on the substrate Sub. The source layer SL is provided on the interlayer insulating film 9.

The substrate Sub is a semiconductor substrate, for example, silicon substrate. The conductivity type of the silicon (Si) is, for example, P-type. An element separation region 10i is provided on, for example, a surface region of the substrate Sub. The element separation region 10i is, for example, an insulating region including silicon oxide (SiO2). An active area AA is provided on the surface region of the substrate Sub. The active area AA and the element separation region 10i are separated from each other on the surface region of the substrate Sub. A source region and a drain region of a transistor Tr are provided on the active area AA. The transistor Tr forms a peripheral circuit, for example, a CMOS (Complementary Metal-Oxide-Semiconductor) circuit of the non-volatile memory. The CMOS circuit is provided under the source layer SL. The CMOS circuit is provided on the substrate Sub.

The interlayer insulating film 9 includes, for example, silicon oxide. The transistor Tr is coated with the interlayer insulating film 9. A wiring 9a is provided inside the interlayer insulating film 9. A part of the wiring 9a is electrically connected to the transistor Tr. As the material of the source layer SL, an electroconductive material, for example, doped silicon, tungsten (W), or the like is used. The source layer SL is formed of a plurality of layers. A part of the source layer SL may include undoped silicon. The source layer SL functions as a source line common to an array region 2m (refer to FIG. 4).

The multi-layered body 2 is provided above the substrate Sub. The multi-layered body 2 is located on a side in the +Z direction with respect to the source layer SL. The multi-layered body 2 includes a plurality of conductive layers 21 and a plurality of insulating films 22. The plurality of the conductive layers 21 and the plurality of the insulating films 22 are alternately stacked one by one in the Z direction. The conductive layer 21 includes an electroconductive metal, for example, tungsten. The insulating film 22 includes, for example, silicon oxide. Two conductive layers 21 adjacent to each other are electrically separated from each other by the insulating film 22. The lamination number of the conductive layers 21 and the lamination number of the insulating films 22 are optionally determined. The insulating film 22 may be, for example, an air gap. Of the plurality of the insulating films 22, an insulating film provided between the multi-layered body 2 and the source layer SL is a lower insulating film 22. For example, the lower insulating film 22 is located at the lowermost position of the plurality of the insulating films 22. For example, the lower insulating film 22 may include a high dielectric having a relative permittivity higher than that of silicon oxide. The high dielectric may be, for example, metal oxide.

Each of the conductive layers 21 includes at least one source-side select gate SGS, the plurality of the word lines WL, and at least one drain-side select gate SGD. The source-side select gate SGS is a gate electrode of a source-side select transistor STS. The word line WL is a gate electrode of the memory cell MC. The drain-side select gate SGD is a gate electrode drain-side select transistor STD. The source-side select gate SGS is provided at a lower region of the multi-layered body 2. The drain-side select gate SGD is provided at an upper region of the multi-layered body 2. The lower region is a region close to the base body 1 in the multi-layered body 2. The upper region is a region far from the base body 1 in the multi-layered body 2. The word line WL is provided between the source-side select gate SGS and the drain-side select gate SGD.

Of the plurality of the insulating films 22, the thickness in the Z direction of the insulating film 22 that insulates the source-side select gate SGS from the word line WL may be thicker than the thickness in the Z direction of the insulating film 22 that insulates, for example, two word lines WL from each other. Furthermore, a cover insulating film (not shown in the drawings) may be provided on the insulating film 22 that is the uppermost layer furthest from the base body 1. The cover insulating film includes, for example, silicon oxide.

The semiconductor storage device 100 includes the plurality of the memory cells MC. The memory cells MC are connected in series between the source-side select transistor STS and the drain-side select transistor STD. A configuration in which the source-side select transistor STS, the memory cell MC, and the drain-side select transistor STD are connected in series is referred to as a “memory string” or “NAND string”. The memory string is connected to each of the bit lines BL via, for example, a contact Cb. The bit lines BL are provided above the multi-layered body 2. The bit lines BL extend in the Y direction.

The plurality of the deep slits ST and the plurality of the shallow slits SHE are provided in the multi-layered body 2. Each of the deep slits ST extends in the X direction. The deep slits ST penetrate through the multi-layered body 2 from an upper end of the multi-layered body 2 to the base body 1. The deep slits ST are provided in the multi-layered body 2. The tabular part 3 is, for example, a wiring provided in the deep slit ST. The tabular part 3 is electrically insulated from the multi-layered body 2 by an insulating film (not shown in the drawings) provided on an inner wall of the deep slits ST. Furthermore, the tabular part 3 is implanted into the deep slits ST. The tabular part 3 is formed of an electroconductive film electrically connected to the source layer SL. Note that, the tabular part 3 may be formed by, for example, filling an insulation material such as a silicon oxide film to the deep slit ST. On the other hand, the shallow slits SHE extend in the X direction from the upper end of the multi-layered body 2. The shallow slits SHE are provided so as to reach the middle of the multi-layered body 2. The shallow slits SHE penetrate through the upper region of the multi-layered body 2. The drain-side select gate SGD is provided in the upper region of the multi-layered body 2. The tabular part 4 is provided in, for example, the shallow slits SHE (refer to FIG. 4). The tabular part 4 is formed of, for example, silicon oxide.

As shown in FIG. 4, the memory cell array 11 includes the multi-layered body 2. The memory cell array 11 includes the array region 2m and a pair of stair regions 2s. Each of the pair of the stair regions 2s is provided at an edge of the multi-layered body 2. The array region 2m is sandwiched between or surrounded by the pair of the stair regions 2s. The deep slits ST are provided so as to extend from the stair region 2s on one end of the multi-layered body 2 to the stair region 2s on the other end of the multi-layered body 2 through the array region 2m. Here, the stair region 2s on one end of the multi-layered body 2 may be referred to as a first stair region. The stair region 2s on the other end of the multi-layered body 2 may be referred to as a second stair region. The shallow slit SHE is provided in at least the array region 2m.

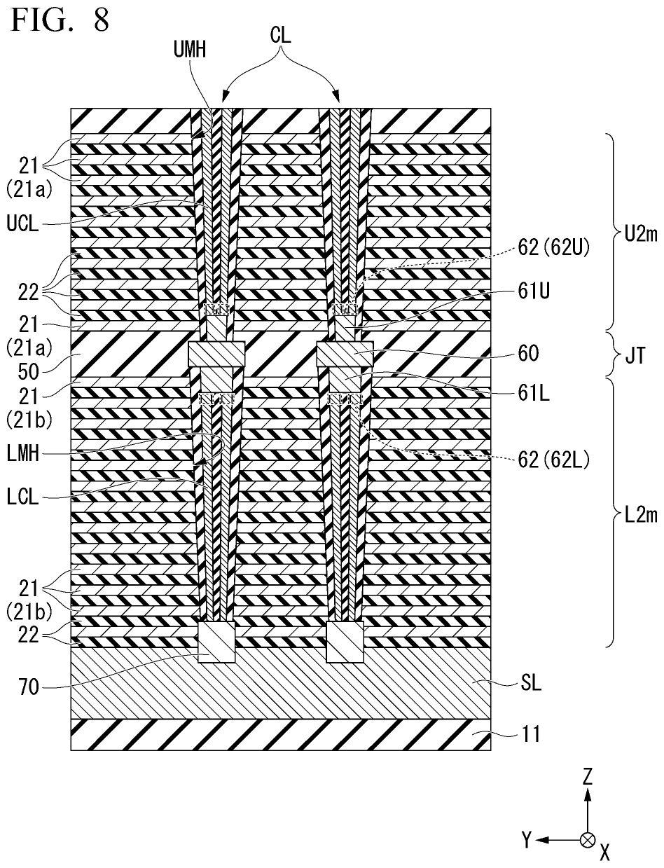

The array region 2m includes a plurality of memory cell transistors MT (refer to FIG. 5). The array region 2m is a region capable of storing data. For example, the array region 2m includes a lower array L2m and an upper array Ulm (refer to FIG. 8) described below. The array region 2m includes a plurality of columnar parts CL provided therein. The plurality of the columnar parts CL are arranged along a plurality of rows in one-to-one correspondence. Each of the rows extends in the X direction. The array region 2m will be described below in detail.

The portion of the multi-layered body 2 sandwiched between two tabular parts 3 shown in FIG. 4 is referred to as a “block”. In FIG. 4, the block is represented by “BLK”. The block BLK forms the minimum unit for, for example, data erase. The tabular part 4 is provided in the block BLK. The multi-layered body 2 located between the tabular part 3 and the tabular part 4 is referred to as a “finger”. The drain-side select gate SGD is divided for each finger. Consequently, when a data write operation and a data read operation are carried out, one finger in the block BLK can be a state of being selected by the drain-side select gate SGD.

### <2. Configuration of Memory Cell Array>

### <2.1 Electrical Configuration of Memory Cell Array>

Next, a configuration of the memory cell array 11 will be described.

FIG. 5 is a view showing an equivalent circuit of a part of the memory cell array 11. FIG. 5 shows one block BLK included in the memory cell array 11. The block BLK includes a plurality of (for example, four) string units SU0 to SU3. Each of the plurality of the string units SU may be referred to as a “finger”.

Each of the plurality of the string units SU includes a plurality of NAND strings NS. The NAND strings NS are associated with the bit lines BL0 to BLm (m is an integer greater than or equal to one) in one-to-one correspondence. Each of the plurality of the NAND strings NS includes, for example, the plurality of the memory cell transistors MT0 to MTn (n is an integer greater than or equal to one), one or more drain-side select transistors STD, and one or more source-side select transistors STS.

In each of the plurality of the NAND strings NS, the memory cell transistors MT0 to MTn are connected in series. Each of the plurality of the memory cell transistors MT includes a control gate and a charge storage part. The control gate of the memory cell transistor MT is connected to any one of the word lines WL0 to WLn. Each of the plurality of the memory cell transistors MT accumulates an electric charge in the charge storage part in accordance with a voltage applied to the control gate via the word line WL. Accordingly, each of the plurality of the memory cell transistors MT stores data non-volatilely.

A drain of the drain-side select transistor STD is connected to the bit line BL corresponding to the NAND string NS. A source of the drain-side select transistor STD is connected to one end of the memory cell transistors MT0 to MTn connected in series. A control gate of the drain-side select transistor STD is connected to any one of the drain-side select gate lines SGD0 to SGD3. The drain-side select transistor STD is electrically connected to the row decoder module 16 via the drain-side select gate line SGD. The drain-side select transistor STD connects the NAND string NS and the bit line BL when a predetermined voltage is applied to the corresponding drain-side select gate line SGD.

A drain of the source-side select transistor STS is connected to the other end of the memory cell transistors MT0 to MTn that are connected in series. A source of the source-side select transistor STS is connected to the source line SL. A control gate of the source-side select transistor STS is connected to the source-side select gate line SGS. The source-side select transistor STS connects the NAND string NS and the source line SL when a predetermined voltage is applied to the source-side select gate line SGS.

In the same block BLK, the control gates of the memory cell transistors MT0 to MTn are mutually connected to the corresponding word lines WL0 to WLn, respectively. The control gates of the drain-side select transistors STD in the string units SU0 to SU3 are commonly connected to the corresponding select gate lines SGD0 to SGD3, respectively. The control gate of the source-side select transistor STS is mutually connected to the source-side select gate line SGS. In the memory cell array 11, the bit line BL is common to the NAND strings NS to which the same column address is assigned for each string unit SU.

### <2.2 Physical Configuration of Memory Cell Array>

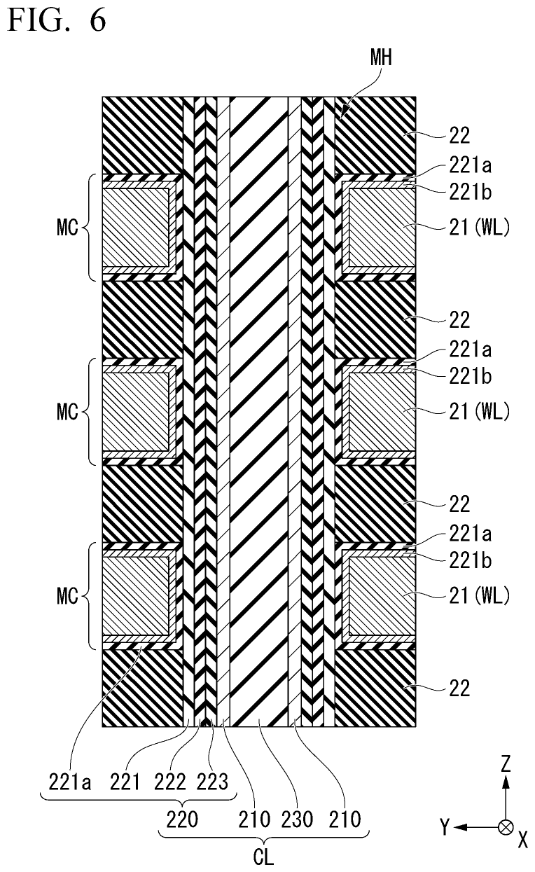

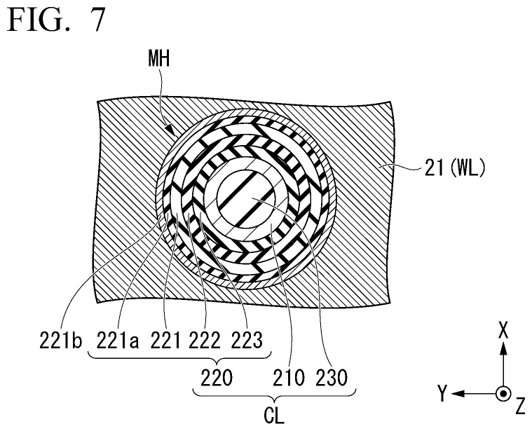

FIG. 6 is a cross-sectional view showing a part of the semiconductor storage device 100. FIG. 7 is a cross-sectional view showing the columnar part CL of the semiconductor storage device 100.

### <2.2.1 Columnar Part>

As shown in FIG. 6, each of the plurality of the columnar parts CL is provided in a memory hole MH formed in the multi-layered body 2. Each of the plurality of the columnar parts CL penetrates through the multi-layered body 2 so as to extend from the upper end of the multi-layered body 2 in the Z direction. Each of the plurality of the columnar parts CL is provided over the inside of the multi-layered body 2 and the inside of the source layer SL (refer to FIG. 3). Each of the plurality of the columnar parts CL includes a semiconductor body 210, a memory film 220, and a core layer 230. The columnar part CL includes the core layer 230, the semiconductor body 210, and the memory film 220. The core layer 230 is provided at a medial portion of the columnar part CL. The semiconductor body 210 is provided around the core layer 230. The memory film 220 is provided around the semiconductor body 210. Here, the “semiconductor body” is an example of a semiconductor layer.

The semiconductor body 210 is electrically connected to the source layer SL. The memory film 220 functioning as the charge storage part includes an electric charge capture part. The electric charge capture part is provided between the semiconductor body 210 and the conductive layers 21. The plurality of the columnar parts CL, each of which is selected from each finger, are commonly connected to one bit line BL via the contact Cb (refer to FIG. 3).

As shown in FIG. 7, the shape of the memory hole MH is, for example, a substantially circular shape or a substantially elliptical shape in plan view when viewed from the Z direction (X-Y plane). A block insulating film 221a may be provided between the conductive layer 21 and the insulating film 22. The block insulating film 221a forms a part of the memory film 220. The block insulating film 221a is, for example, a silicon oxide film or a metal oxide film. An example of the metal oxide is aluminum oxide. A barrier film 221b may be provided between the conductive layer 21 and the insulating film 22 and between the conductive layer 21 and the memory film 220. In a case in which, for example, the conductive layer 21 is formed of tungsten, for example, titanium nitride is selected as the barrier film 221b. The block insulating film 221a suppresses back tunneling of an electric charge from the conductive layer 21 to the memory film 220. The barrier film 221b improves adhesion of the conductive layer 21 and the block insulating film 221a.

The shape of the semiconductor body 210 is, for example, a tubular shape having a bottom. The semiconductor body 210 includes, for example, silicon. Silicon is, for example, polysilicon obtained by crystallizing amorphous silicon. The semiconductor body 210 is, for example, undoped silicon. Moreover, the semiconductor body 210 may be P-type silicon. The semiconductor body 210 functions as a channel for each of the drain-side select transistor STD, the memory cell MC, and the source-side select transistor STS.

The memory film 220 includes a memory film portion that is other than the block insulating film 221a. The memory film portion is provided between an inner wall of the memory hole MH and the semiconductor body 210. The shape of the memory film 220 is, for example, a tubular shape. Each of the plurality of the memory cells MC includes a storage area. The plurality of the memory cells MC are laminated in the Z direction. The storage area is located between the semiconductor body 210 and the conductive layer 21. The conductive layer 21 functions as the word line WL. The memory film 220 includes, for example, a cover insulating film 221, a charge storage film 222, and a tunnel insulating film 223. Each of the semiconductor body 210, the cover insulating film 221, the charge storage film 222, and the tunnel insulating film 223 extends in the Z direction.

The cover insulating film 221 is provided between the insulating film 22 and the charge storage film 222 and between the block insulating film 221a and the charge storage film 222. The cover insulating film 221 includes, for example, silicon oxide.

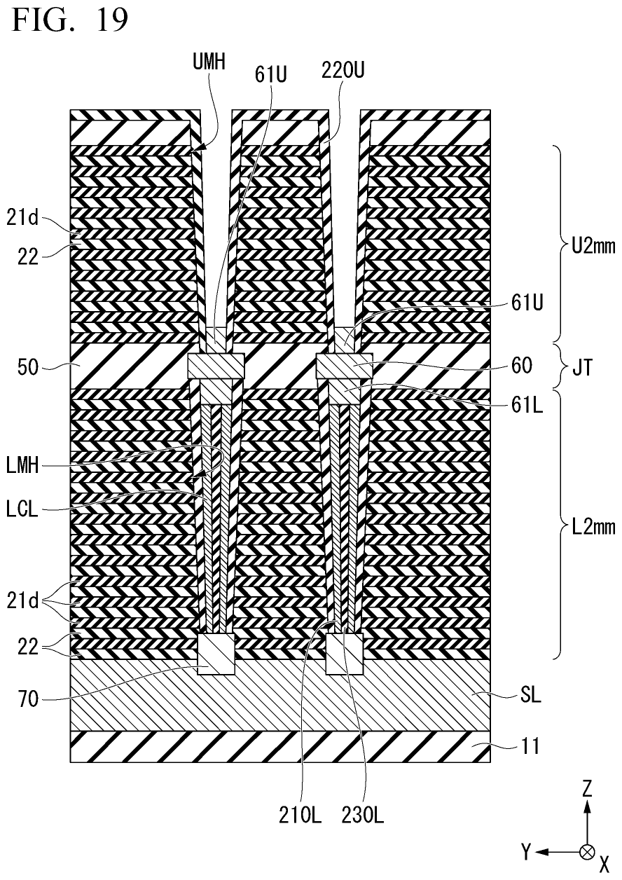

The cover insulating film 221 protects the charge storage film 222 so as not to be etched when replacing a sacrificial film (for example, reference numeral 21d shown in FIG. 19) with the conductive layer 21 (replacing step).

The charge storage film 222 is provided between the cover insulating film 221 and the tunnel insulating film 223. The cover insulating film 221 is provided between the block insulating film 221a and the charge storage film 222. The charge storage film 222 includes, for example, silicon nitride. The charge storage film 222 has a trap site that traps an electric charge in the film. The charge storage film 222 has a portion sandwiched between the semiconductor body 210 and the conductive layer 21 functioning as the word line WL. The sandwiched portion forms the storage area of the memory cell MC serving as the electric charge capture part. A threshold voltage of the memory cell MC varies depending on the presence or absence of an electric charge in the electric charge capture part or depending on an amount of electric charge captured by the electric charge capture part. Consequently, the memory cell MC holds information (data).

The tunnel insulating film 223 is provided between the semiconductor body 210 and the charge storage film 222. The tunnel insulating film 223 includes, for example, silicon oxide or both of silicon oxide and silicon nitride. The tunnel insulating film 223 is an electrical potential barrier between the semiconductor body 210 and the charge storage film 222. Each of an electron and a hole passes through the electrical potential barrier of the tunnel insulating film 223 (tunneling), for example, when injecting the electron from the semiconductor body 210 to the electric charge capture part (write operation), and when injecting the hole from the semiconductor body 210 to the electric charge capture part (erase operation).

The inside space of the tubular-shaped semiconductor body 210 is filled with the core layer 230. The shape of the core layer 230 is, for example, a pillar shape. The core layer 230 includes, for example, silicon oxide, and has insulation.

The columnar parts CL, that is, the memory holes MH are arranged between two deep slits ST adjacent to each other in the Y direction so as to have, for example, a hexagonal closest packed structure in a planar layout. The shallow slit SHE may be provided at a part of the columnar part CL so as to overlap the columnar part CL. The memory cell MC is not formed at the columnar part CL located under the shallow slit SHE.

The above-described three-dimensional memory cell array 11 may be formed by a plurality of steps with an increase in the number of layers constituting the multi-layered structure. The reason for this is, as the multi-layered body of the memory cell array 11 becomes thicker, it becomes difficult to form the memory hole MH to have a desired shape. For this reason, as shown in FIG. 8, the memory cell array 11 according to the embodiment has a configuration obtained by separately forming two multi-layered bodies, that is, the lower array L2m and the upper array U2m. Here, the “lower array L2m” is, for example, a first multi-layered body. The “upper array U2m” is, for example, a second multi-layered body.

FIG. 8 is a cross-sectional view showing a part of the semiconductor storage device 100. Specifically, FIG. 8 is a cross-sectional view showing a more specific configuration example of the array region 2m of the memory cell array 11. The array region 2m includes the lower array L2m and the upper array U2m.

The lower array L2m is provided on the source layer SL. The lower array L2m includes a plurality of conductive layers 21a and the plurality of the insulating films 22. The plurality of the conductive layers 21a and the plurality of the insulating films 22 are alternately stacked one by one in the Z direction. Here, the “conductive layer 21a” is an example of a first conductive layer. Two conductive layers 21a adjacent to each other in the Z direction are electrically isolated from each other by the insulating film 22. The lower array L2m is electrically connected to the source layer SL via an epitaxial silicon layer 70. Note that, in a case in which the source layer SL is formed of silicon single crystal, the epitaxial silicon layer 70 can be grown on the source layer SL.

The upper array U2m is provided above the lower array L2m. The upper array U2m includes a plurality of conductive layers 21b and the plurality of the insulating films 22. The plurality of the conductive layers 21b and the plurality of the insulating films 22 are alternately stacked one by one in the Z direction. Here, the “conductive layer 21b” is an example of a second conductive layer. Two conductive layers 21b adjacent to each other in the Z direction are electrically isolated from each other by the insulating film 22. The insulating film 22 is provided between the conductive layers 21a adjacent to each other in the Z direction and between the conductive layers 21b adjacent to each other in the Z direction. The insulating film 22 electrically separates the conductive layers 21a from each other. The insulating film 22 electrically separates the conductive layers 21b from each other.

The plurality of the columnar parts CL are provided in the upper array U2m and the lower array L2m so as to extend in the Z direction. Each of the plurality of the columnar parts CL includes a lower columnar part LCL and an upper columnar part UCL. Here, the “lower columnar part LCL” is an example of a first columnar part. The “upper columnar part UCL” is an example of a second columnar part.

The lower columnar part LCL is provided in the lower array L2m so as to extend in the Z direction. The lower columnar part LCL penetrates through the lower array L2m and reaches the source layer SL. The upper columnar part UCL is provided in the upper array U2m so as to extend in the Z direction. The upper columnar part UCL penetrates through the upper array U2m. Each of the upper columnar part UCL and the lower columnar part LCL has the configuration described with reference to FIGS. 6 and 7. Thus, the upper columnar part UCL includes the memory film 220, the semiconductor body 210, and the core layer 230 shown in FIGS. 6 and 7 in an upper memory hole UMH. The lower columnar part LCL includes the memory film 220, the semiconductor body 210, and the core layer 230 shown in FIGS. 6 and 7 in a lower memory hole LMH.

A joint part JT is provided between the upper array U2m and the lower array L2m. An interlayer 50, an electrode body 60, and an electrode part 61 are provided in the joint part JT. The interlayer 50 is formed of an insulating film, for example, a silicon oxide film, a silicon oxide layer, or the like.

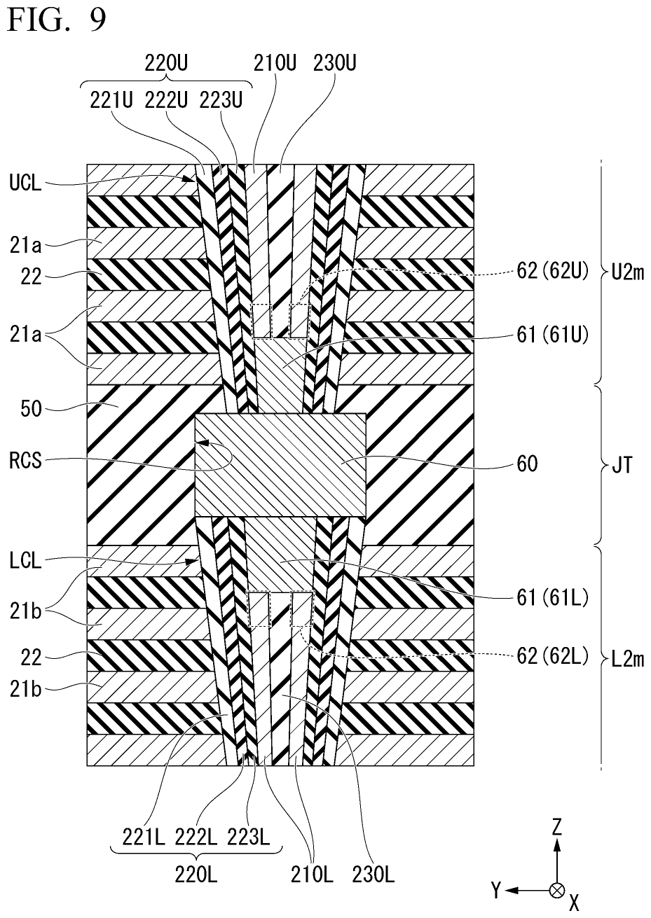

FIG. 9 is an enlarged cross-sectional view showing a region close to the electrode part 61 of the semiconductor storage device 100. That is, FIG. 9 is an enlarged cross-sectional view showing an example of a structure located close to the joint part JT between the upper array U2m and the lower array L2m. Note that, the memory film 220, the charge storage film 222, the semiconductor body 210, and the core layer 230 of the lower columnar part LCL are referred to as a memory film 220L, a charge storage film 222L, a semiconductor body 210L and a core layer 230L, respectively, for sake of simplicity. The memory film 220, the charge storage film 222, the semiconductor body 210, and the core layer 230 of the upper columnar part UCL are referred to as a memory film 220U, a charge storage film 222U, a semiconductor body 210U, and a core layer 230U, respectively, for sake of simplicity. Here, the “charge storage film 222L” is an example of a first charge storage film. The “semiconductor body 210L” is an example of a first semiconductor layer. Additionally, the “charge storage film 222U” is an example of a second charge storage film. The “semiconductor body 210U” is an example of a second semiconductor layer.

The joint part JT is provided between the upper array U2m and the lower array L2m. The interlayer 50, the electrode body 60, and the electrode part 61 are provided in the joint part JT.

The interlayer 50 is retracted in a direction (the X direction and the Y direction) away from a center of the columnar part CL. This means that the interlayer 50 is depressed from the upper array U2m and the lower array L2m in at least one of the X direction and the Y direction in the joint part JT. The interlayer 50 forms a recess RCS. The interlayer 50 is formed of an insulating film, for example, a silicon oxide film, a silicon oxide layer, or the like.

The recess RCS is filled with the electrode body 60. The electrode body 60 is provided between the upper columnar part UCL and the lower columnar part LCL. The electrode body 60 separates the upper columnar part UCL and the lower columnar part LCL from each other over the entirety of the upper columnar part UCL and the lower columnar part LCL. That is, the electrode body 60 separates the memory film 220U and the memory film 220L from each other in a portion between the upper columnar part UCL and the lower columnar part LCL. Note that, the electrode body 60 may be omitted. In the case of omitting the electrode body 60, the inside wall of the recess RCS may be covered with an insulating film. For example, the inside wall of the recess RCS may be covered with the interlayer 50. In the case in which the electrode body 60 is provided in the recess RCS, the electrode body 60 is formed of polysilicon (Poly-Si) containing impurities (for example, phosphorus (P)) doped therein in a manner similar to those of electrode parts 61L and 61U described below.

The lower columnar part LCL has an upper end. The upper columnar part UCL has a lower end. The electrode part 61 is provided in at least one of an inside of the upper end of the lower columnar part LCL and an inside of the lower end of the upper columnar part UCL. Although FIG. 9 shows the case in which the external form of each of the plurality of the electrode parts 61 is formed is a cylindrical shape, each of the plurality of the electrode parts 61 may be a rectangular parallelepiped shape, a conical shape, or the like. Each of the plurality of the electrode parts 61 is formed of polysilicon (Poly-Si) containing impurities (for example, phosphorus (P)) doped therein. Note that, the electrode part 61 of the lower columnar part LCL is referred to as an electrode part 61L for sake of simplicity, and the electrode part 61 of the upper columnar part UCL is referred to as an electrode part 61U for convenience. Here, the “electrode part 61L” is an example of a first electrode part. The “electrode part 61U” is an example of a second electrode part.

The end portion of the electrode part 61L on the side in the +Z direction protrudes toward the inside of the interlayer 50. That is, the upper end of the electrode part 61L on the side in the +Z direction is located above the upper surface of the conductive layer 21b located at the uppermost position of the plurality of the conductive layers 21b. Here, the conductive layer located at the uppermost position of the plurality of the conductive layers 21b may be referred to as the uppermost conductive layer. On the other hand, the end portion of the electrode part 61L on the side in the −Z direction is located under the position of the conductive layer 21b located at the uppermost position of the plurality of the conductive layers 21b. Particularly, in a cross-sectional view when viewed from the X direction, the electrode part 61L is sandwiched between two conductive layers 21b located at the uppermost position of the plurality of the conductive layers 21b.

The end portion of the electrode part 61U on the side in the −Z direction protrudes toward the inside of the interlayer 50. That is, the lower end of the electrode part 61U on the side in the −Z direction is located under the lower surface of the conductive layer 21a located at the lowermost position of the plurality of the conductive layers 21a. Here, the conductive layer located at the lowermost position of the plurality of the conductive layers 21a may be referred to as the lowermost conductive layer. On the other hand, the end portion of the electrode part 61U on the side in the +Z direction is located above the position of the conductive layer 21a located at the lowermost position of the plurality of the conductive layers 21a. Particularly, in a cross-sectional view when viewed from the X direction, the electrode part 61U is sandwiched between two conductive layers 21a located at the lowermost position of the plurality of the conductive layers 21a.

As described below, each of the electrode parts 61L and 61U functions as a GIDL generation electrode that assists a GIDL current. For this reason, it is preferable that both the electrode parts 61L and 61U be provided on the electrode body 60. However, one of the electrode parts 61L and 61U may be provided on the electrode body 60.

In a case in which the electrode body 60 is provided at the joint part JT, it is preferable that the electrode parts 61L and 61U be electrically connected to the electrode body 60. For example, it is preferable that each of the electrode parts 61L and 61U be configured to protrude from the end surfaces of the electrode body 60 toward the columnar part CL. In this structure, it is preferable that the electrode body 60 and the electrode parts 61L and 61U be configured of the same material as each other.

The length of the electrode part 61L in the Y direction may be substantially the same as that of the semiconductor body 210L in the Y direction. The length of the electrode part 61U in the Y direction may be substantially the same as that of the semiconductor body 210U in the Y direction. Furthermore, as shown in the case of the semiconductor storage device 100 obtained by separately forming the lower array L2m and the upper array U2m, the shape of each of the plurality of the columnar parts CL is often a substantially conical shape such that the length thereof in the Y direction gradually increases in the +Z direction. As stated above, in the case in which the shape of each of the plurality of the columnar parts CL is a substantially conical shape, it is preferable that each of the plurality of the electrode parts 61 also be a substantially conical in shape. That is, it is preferable that the outer diameter of each of the plurality of the electrode parts 61 be substantially the same as that of each of the plurality of the semiconductor bodies 210.

As shown in FIG. 9, the semiconductor storage device 100 includes an impurity-diffusion region 62 in each of the lower array L2m and the upper array U2m. In the lower array L2m, the impurity-diffusion region 62 protrudes from the end surface of the electrode part 61L toward the inside of the semiconductor body 210L in the Z direction. In the upper array U2m, the impurity-diffusion region 62 protrudes from the end surface of the electrode part 61U toward the inside of the semiconductor body 210U in the Z direction. The impurity-diffusion region 62 is a region having N-type impurities diffused therein. Specifically, the N-type impurities are diffused from a contacting surface between the electrode part 61L and the semiconductor body 210L toward the lower array L2m in the semiconductor body 210L. Also, the N-type impurities are diffused from a contacting surface between the electrode part 61U and the semiconductor body 210U toward the upper array U2m in the semiconductor body 210U. Note that, for sake of simplicity of explanation, the impurity-diffusion region 62 inside the semiconductor body 210L is referred to as an impurity-diffusion region 62L. The impurity-diffusion region 62 inside the semiconductor body 210U is referred to as an impurity-diffusion region 62U. Here, the “impurity-diffusion region 62L” is an example of a first impurity-diffusion region. The “impurity-diffusion region 62U” is an example of a second impurity-diffusion region.

The impurity-diffusion region 62L is a region in which the N-type impurity dopant (for example, phosphorus (P)) contained in the electrode part 61L is diffused inside the semiconductor body 210L by thermal diffusion. The impurity-diffusion region 62U is a region in which the N-type impurity dopant (for example, phosphorus (P)) contained in the electrode part 61U is diffused inside the semiconductor body 210U by thermal diffusion. That is, during the data erase operation, it is possible to generate holes at the upper portion of the semiconductor body 210L and the periphery of the lower portion of the semiconductor body 210U by the impurity-diffusion regions 62L and 62U.

The impurity-diffusion region 62L extends toward the inside of the semiconductor body 210L from the lower surface of the electrode part 61L in the Z direction. The lower end position of the impurity-diffusion region 62L is not particularly limited. For example, it is preferable that the impurity-diffusion region 62L extend such that the lower end position of the impurity-diffusion region 62L reaches at least the second place of the plurality of the conductive layers 21b from above. For example, the impurity-diffusion region 62L may be provided so as to face the conductive layer 21b closest to the lower end of the electrode part 61L in the Y direction. More preferably, for example, it is preferable that the impurity-diffusion region 62L extend such that the lower end position of the impurity-diffusion region 62L reaches the third place of the plurality of the conductive layers 21b from above. Note that, the number of the conductive layers 21b facing the impurity-diffusion region 62L in the Y direction is not limited to one. In the configuration shown in FIG. 9, the number of the conductive layers 21b facing the impurity-diffusion region 62L is only one. For example, in a case in which the length of the impurity-diffusion region 62L in the Z direction is larger, a configuration may be adopted in which the impurity-diffusion region 62L faces the plurality of the conductive layers 21b.

The impurity-diffusion region 62U extends toward the inside of the semiconductor body 210U from the upper surface of the electrode part 61U in the Z direction. The upper end position of the impurity-diffusion region 62U is not particularly limited. For example, it is preferable that the impurity-diffusion region 62U extend such that the upper end position of the impurity-diffusion region 62U reaches at least the second place of the plurality of the conductive layers 21a from below. For example, the impurity-diffusion region 62U may be provided so as to face the conductive layer 21a closest to the upper end of the electrode part 61U in the Y direction. More preferably, for example, it is preferable that the impurity-diffusion region 62U extend such that the upper end position of the impurity-diffusion region 62U reaches the third place of the plurality of the conductive layers 21a from below. Note that, the number of the conductive layers 21a facing the impurity-diffusion region 62U in the Y direction is not limited to one. In the configuration shown in FIG. 9, the number of the conductive layers 21a facing the impurity-diffusion region 62U is only one. For example, in a case in which the length of the impurity-diffusion region 62U in the Z direction is larger, a configuration may be adopted in which the impurity-diffusion region 62U faces the plurality of the conductive layers 21a.

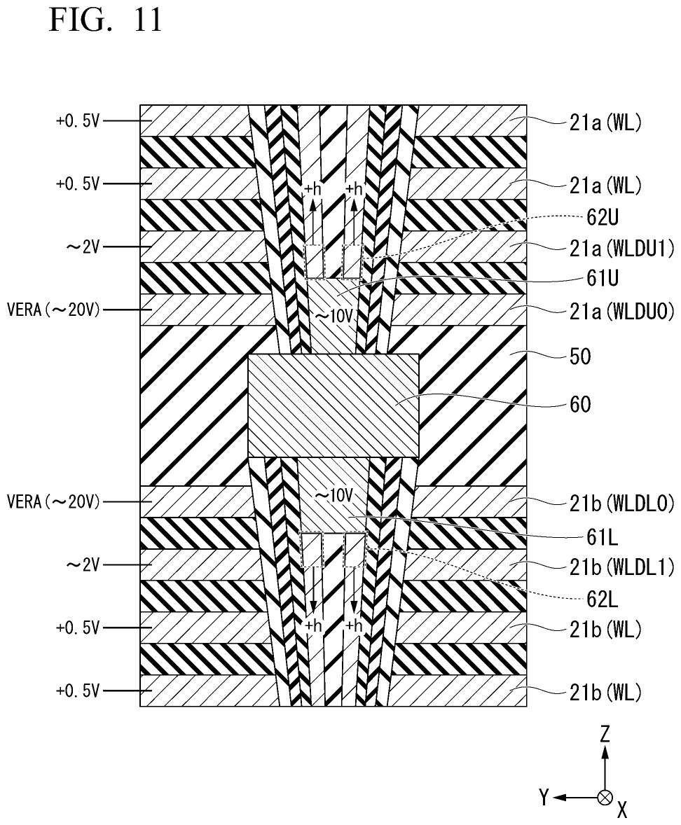

Here, the plurality of the conductive layers 21b constituting the lower array L2m include the conductive layer 21b facing the impurity-diffusion region 62L. The conductive layer 21b facing the impurity-diffusion region 62L functions as a dummy word line WLDL1 described below (for example, refer to FIG. 11). The conductive layer 21b located under the dummy word line WLDL1 functions as a word line. Furthermore, the plurality of the conductive layers 21b constituting the lower array L2m include an uppermost conductive layer 21b. The uppermost conductive layer 21b is the conductive layer located at the uppermost position of the plurality of the conductive layers 21b. The number of the uppermost conductive layers 21b may be one or more. The uppermost conductive layer 21b is located near the upper array U2m. The uppermost conductive layer 21b is located above the dummy word line WLDL1. The uppermost conductive layer 21b functions as a dummy word line WLDL0 (for example, refer to FIG. 11). Similarly, the plurality of the conductive layers 21a constituting the upper array U2m include the conductive layer 21a facing the impurity-diffusion region 62U. The conductive layer 21a facing the impurity-diffusion region 62U functions as a dummy word line WLDL1 described below (for example, refer to FIG. 11). The conductive layer 21a located above the dummy word line WLDL1 functions as a word line. Furthermore, the plurality of the conductive layers 21a constituting the upper array U2m include a lowermost conductive layer 21a. The lowermost conductive layer 21a is the conductive layer located at the lowermost position of the plurality of the conductive layers 21a. The number of the lowermost conductive layers 21a may be one or more. The lowermost conductive layer 21a is located near the lower array L2m. The lowermost conductive layer 21a is located under the dummy word line WLDL1. The lowermost conductive layer 21a functions as a dummy word line WLDL0 (for example, refer to FIG. 11).

As described below, each of the dummy word lines WLDL0 is a conductive layer that applies a predetermined voltage (approximately, 10V) to the electrode part 61 due to capacitor coupling.

A state in which impurities are diffused in the impurity-diffusion region 62 can be evaluated by element mapping using, for example, energy dispersive X-ray spectroscopy (EDS). For example, in a case of using phosphorus (P)-doped silicon as the material of the electrode part 61, the P-concentration of the impurity-diffusion region 62 is, for example, approximately 5×10²⁰ cm⁻³. The impurity-diffusion region 62 is obtained by thermally diffusing the impurities by annealing after the semiconductor body 210 is formed.

### <3. Basic Action of Semiconductor Storage Device>

Next, an erase operation of a basic action of the semiconductor storage device 100 will be described.

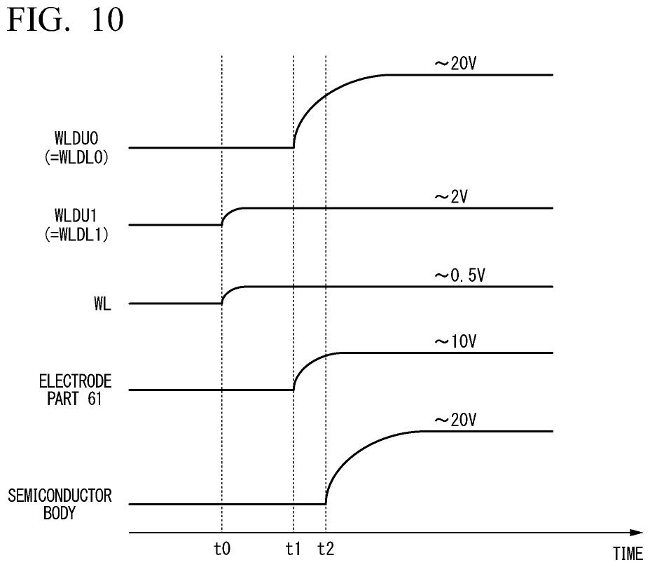

FIG. 10 is a timing chart showing a voltage of each of wirings when applying an erasing pulse in a block erase operation. FIGS. 11 to 13 are cross-sectional views explaining an erase operation of the semiconductor storage device 100.

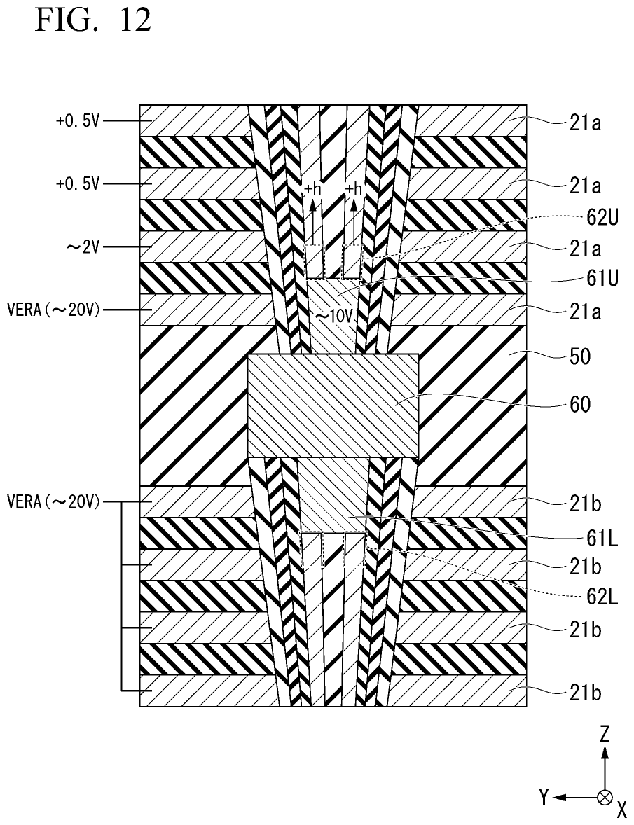

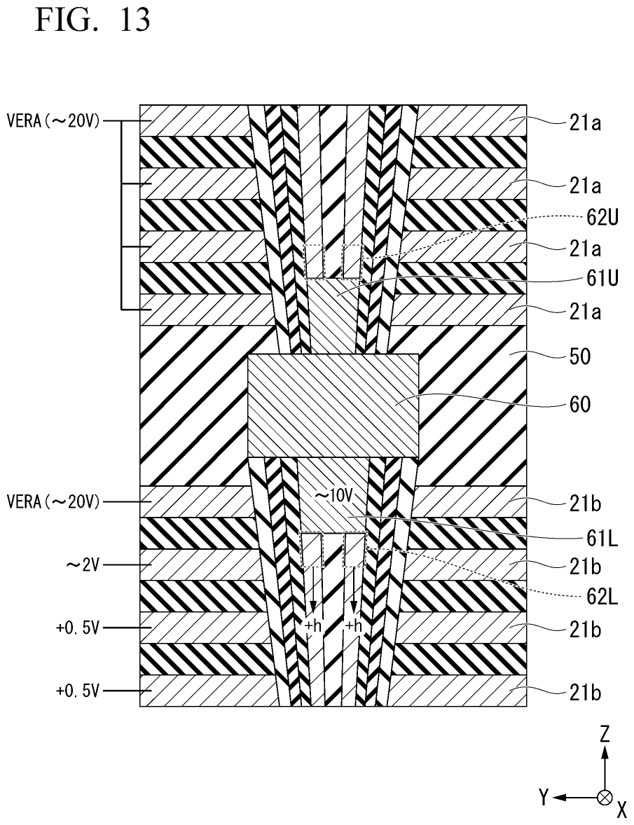

In examples shown in FIGS. 10 and 11, a block erase operation will be described. In the block erase operation, one block BLK is selected, and an erase operation is executed. In examples shown in FIGS. 12 and 13, a sub-block erase operation will be described. In the sub-block erase operation, the lower array L2m and the upper array U2m are used as different individual blocks (sub blocks), and an erase operation is executed.

In the semiconductor storage device 100 according to the first embodiment, a reverse bias voltage is applied between the gate and the drain of at least one select transistor of the drain-side select transistor STD and the source-side select transistor STS. Furthermore, a reverse bias voltage is also applied between the electrode part 61 and the word line (conductive layer 21) located close to the electrode part 61. Consequently, the erase operation is carried out by generating Gate-Induced Drain Leakage (GIDL). Due to the generation of the GIDL, it is possible to extinguish an electric charge of the charge storage film by injecting a hole thereto via the channel of the memory cell transistor MT.

The erase operation generally includes an erasing-pulse application operation and an erase-verify-operation. The erasing-pulse application operation is an operation of applying an erasing pulse for lowering a threshold voltage of the memory cell transistor MT. The erase-verify-operation is an operation of determining whether or not the threshold voltage of the memory cell transistor MT is lower than a target value, based on the result of carrying out the erasing-pulse application operation. In the erase operation, the combination of the erasing-pulse application operation and the erase-verify-operation is repeatedly carried out, and therefore the threshold voltage of the memory cell transistor MT is lowered until the threshold voltage reaches an erase level.

FIG. 10 is a timing chart showing a voltage of each of wirings when applying an erasing pulse in a block erase operation shown in FIG. 11. First of all, a predetermined voltage is applied to the data word lines WL and the dummy word lines WLDU1 and WLDL1 of the block BLK to be erased (time t0). Regarding the voltage applied to the dummy word lines WLDU1 and WLDL1, in order to prevent each word line WL from being degraded, a midpoint potential between the dummy word line WLDU0 and the data word line WL is applied to the dummy word lines WLDU1, and a midpoint potential between the dummy word line WLDL0 and the data word line WL is applied to the dummy word lines WLDL1. Next, a predetermined voltage is applied to each of the dummy word lines WLDU0, WLDL0 (time t1). Accordingly, a predetermined voltage is applied to each of the plurality of the electrode parts 61 due to capacitor coupling (time t1), and the GIDL current flows to the semiconductor body 210 serving as the channel. In the embodiment, it is difficult to directly apply a voltage to the electrode part 61. For this reason, the upper and lower conductive layers 21 adjacent to the electrode part 61 are used as the dummy word lines WLDU0 and WLDL0, and a voltage Vera (approximately, 20V) is applied to the dummy word lines WLDU0 and WLDL0. Consequently, a predetermined voltage (approximately, 10V) is applied to each of the plurality of the electrode parts 61 due to capacitor coupling. The voltage Vera is a high voltage for generating the GIDL.

The number of the dummy word lines WLDU1 and the number of the dummy word lines WLDL1 are not particularly limited, and may be one or more.

FIG. 12 shows an erase operation in which only the upper array U2m is set as a block to be erased (selected block) and the lower array L2m is not to be erased. On the other hand, FIG. 13 shows an erase operation in which only the lower array L2m is set as a block to be erased (selected block) and the upper array U2m is not to be erased.

As shown in FIGS. 12 and 13, in the semiconductor storage device 100 according to the embodiment, the multi-layered structure including the upper array U2m and the lower array L2m is obtained. In the multi-layered structure, the electrode part 61 serving as an electrode for generation of GIDL is provided between the upper array U2m and the lower array L2m (that is, the joint part JT). Therefore, sub-block erasing can also be executed.

### <4. Method of Manufacturing Semiconductor Storage Device>

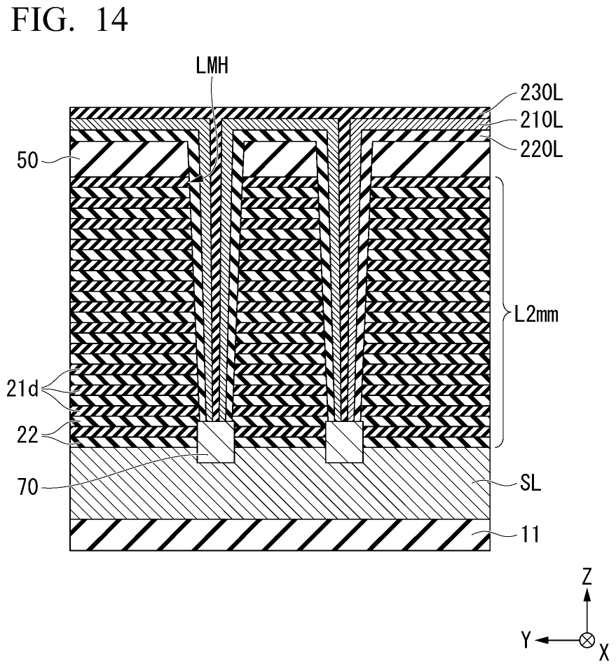

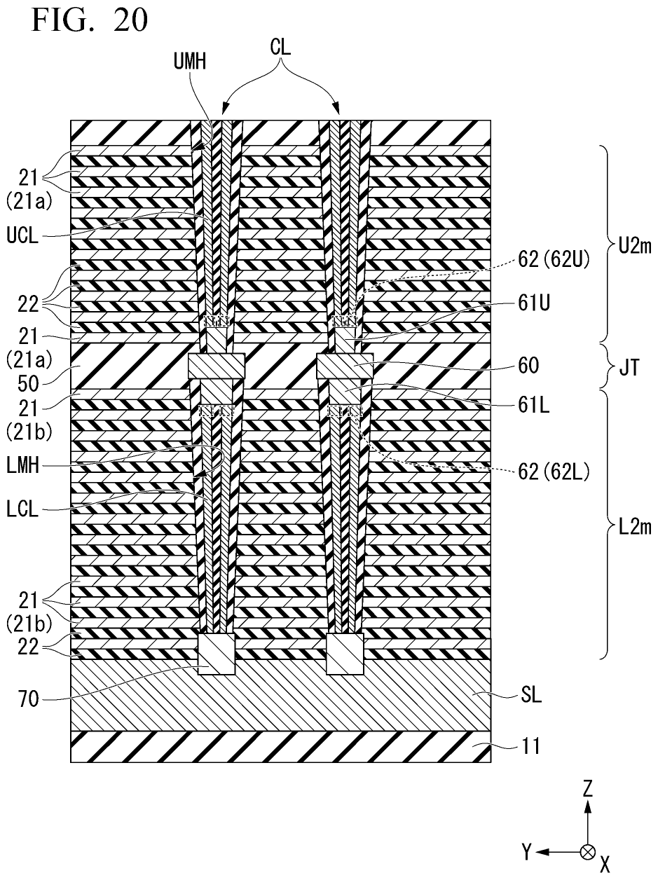

Next, a method of manufacturing the semiconductor storage device 100 will be described with reference to FIGS. 3 and 14 to 20. FIGS. 14 to 20 are cross-sectional views explaining a method of manufacturing the semiconductor storage device 100. Note that, materials described below are merely examples. The materials shown in the embodiment are not particularly limited.

As shown in FIG. 3, firstly, the transistor Tr (CMOS circuit) is formed on the substrate Sub. The transistor Tr is coated with the interlayer insulating film 9. The wiring 9a is formed in the interlayer insulating film 9. The source layer SL is formed on the interlayer insulating film 9. Accordingly, the base body 1 is formed.

Next, as shown in FIG. 14, a plurality of sacrificial films 21d and a plurality of insulating films 22 are alternately stacked in layers above the base body 1 in the Z direction. Consequently, a multi-layered body L2 mm including the sacrificial films 21d and the insulating films 22 is formed on a region of the lower array L2m. For example, an insulation material such as silicon nitride or the like is used for the sacrificial film 21d. For example, an insulation material such as silicon oxide or the like is used for the insulating film 22. The sacrificial films 21d are stacked in layers in the Z direction. The sacrificial films 21d are separated from each other by the insulating film 22. Note that, the sacrificial film 21d is replaced with the conductive layer 21b in the subsequent process.

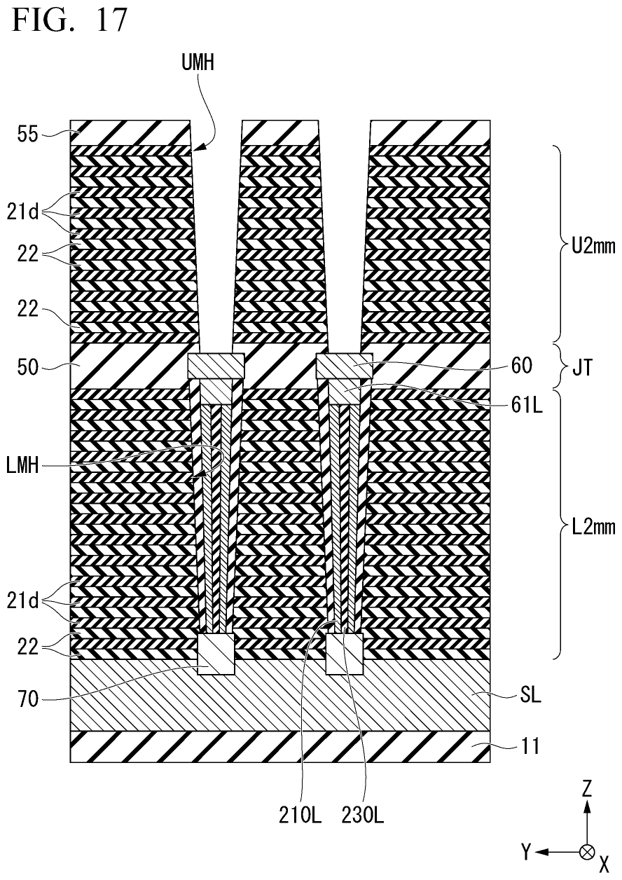

Next, a part of the interlayer 50 is formed on the multi-layered body L2 mm. For example, a silicon oxide film is used for the interlayer 50. The remaining portion of the interlayer 50 is formed in a step before forming a multi-layered body U2 mm (refer to FIG. 17).

Next, the lower memory hole LMH is provided in the interlayer 50 and the multi-layered body L2 mm so as to extend in the Z direction by use of a lithography technique, an RIE (Reactive Ion Etching) method, or the like. Therefore, the lower memory hole LMH that penetrates through the multi-layered body L2 mm is formed. Note that, in a case in which the source layer SL is formed of silicon single crystal, the epitaxial silicon layer 70 can be grown on the source layer SL. In a case in which the source layer SL is formed of another electroconductive material, the epitaxial silicon layer 70 may be omitted. Additionally, the connection structure between the source layer SL and the lower memory hole LMH is not limited to the above, and another structure optionally selected may be adopted.

Next, the epitaxial silicon layer 70 is formed on a bottom portion of the lower memory hole LMH. The epitaxial silicon layer 70 is a silicon layer containing highly-concentrated impurities. The epitaxial silicon layer 70 is electrically connected to the source layer SL.

Next, the memory film 220L and the semiconductor body 210L are formed on an inner wall of the lower memory hole LMH. For example, a cover insulating film 221L, the charge storage film 222L, and a tunnel insulating film 223L are deposited on the inner wall of the lower memory hole LMH in this order. Next, the semiconductor body 210L is formed on an inner wall of the tunnel insulating film 223L. Next, the memory film 220L and the semiconductor body 210L located on the bottom portion of the lower memory hole LMH are removed while leaving the memory film 220L and the semiconductor body 210L located on a side wall of the lower memory hole LMH.

Next, the core layer 230L is formed in the lower memory hole LMH and on an upper surface of the semiconductor body 210L. The core layer 230L is formed such that the inside space of the lower memory hole LMH is filled with the core layer 230L. The core layer 230L includes, for example, silicon oxide. The core layer 230L has insulation. Accordingly, the configuration shown in FIG. 14 is obtained.

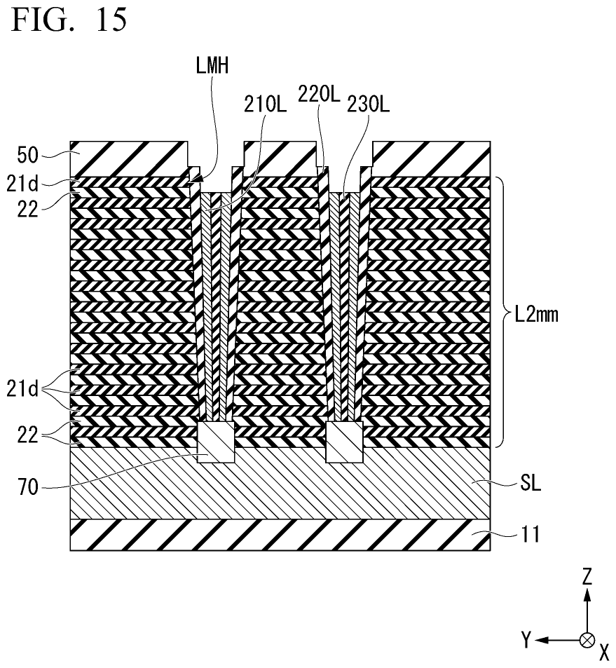

Next, as shown in FIG. 15, a part of the memory film 220L, the semiconductor body 210L, and the core layer 230L is removed such that at least part of an upper surface of the interlayer 50 and a side surface of the interlayer 50 is exposed. At this time, the semiconductor body 210L and the core layer 230L are removed until the upper surfaces of the semiconductor body 210L and the core layer 230L become lower than the upper surface of the memory film 220L. Accordingly, the configuration shown in FIG. 15 is obtained.

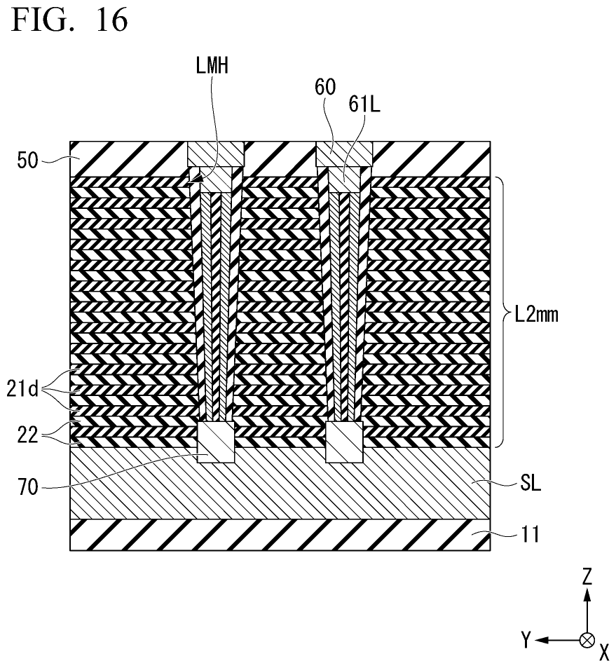

Next, as shown in FIG. 16, the electrode body 60 and the electrode part 61L are provided above the memory film 220L, the semiconductor body 210L, and the core layer 230L so as to be implanted into a space between the interlayers 50. As a method of forming the electrode body 60 and the electrode part 61L, the following method is applicable. First, a silicon film containing impurities (for example, phosphorus (P)) doped therein is formed above the interlayer 50, the memory film 220L, the semiconductor body 210L, and the core layer 230L. Thereafter, the silicon film on the interlayer 50 is removed. At this time, it is preferable that the position of the upper surface of the electrode body 60 be substantially the same as that of the upper surface of the interlayer 50.

Next, as shown in FIG. 17, the remaining portion of the interlayer 50 is formed on the interlayer 50 and the electrode body 60. Moreover, the plurality of the sacrificial films 21d and the plurality of the insulating films 22 are alternately stacked in layers in the Z direction. Consequently, the multi-layered body U2 mm including the sacrificial films 21d and the insulating films 22 is formed on a region of the upper array U2m. The materials of the sacrificial film 21d and the insulating film 22 of the multi-layered body U2 mm are the same as those of the sacrificial film 21d and the insulating film 22 of the multi-layered body L2 mm, respectively. The sacrificial films 21d of the multi-layered body U2 mm are stacked in layers in the Z direction. The sacrificial films 21d are separated from each other by the insulating film 22. Note that, the sacrificial film 21d of the multi-layered body U2 mm is replaced with the conductive layer 21a in the subsequent process.

Next, an insulating film 55 is formed on the multi-layered body U2 mm.

Next, as shown in FIG. 17, the upper memory hole UMH is provided in a part of the insulating film 55, the multi-layered body U2 mm, and the interlayer 50 so as to extend in the Z direction by use of a lithography technique, an RIE method, or the like. Therefore, the upper memory hole UMH that penetrates through the multi-layered body U2mm is formed. The upper memory hole UMH is formed so as to reach the electrode body 60. Accordingly, the configuration shown in FIG. 17 is obtained.

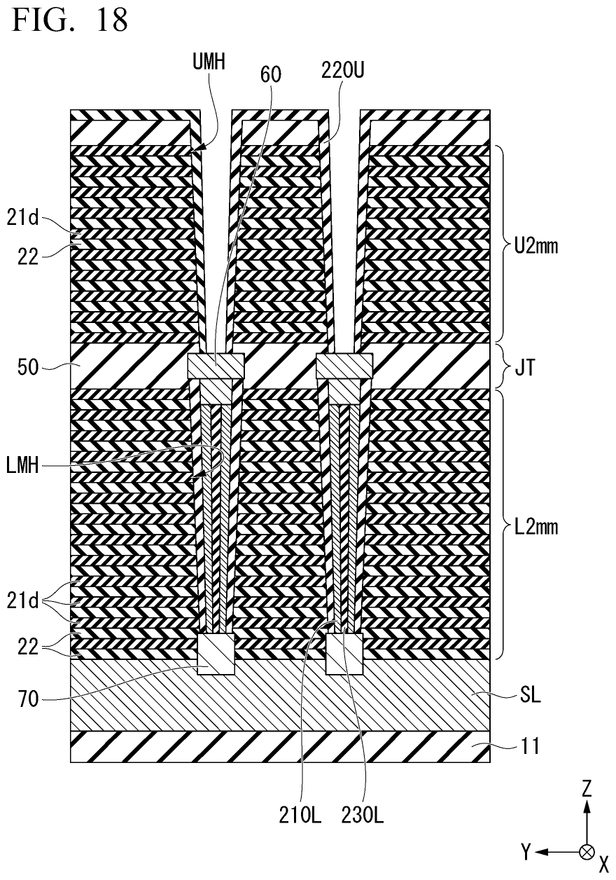

Next, the memory film 220U is formed on an inner wall of the upper memory hole UMH. For example, a cover insulating film 221U, the charge storage film 222U, and a tunnel insulating film 223U are deposited on the inner wall of the upper memory hole UMH in this order. Next, the memory film 220U is etched back. Consequently, the memory film 220U located on the bottom portion of the upper memory hole UMH is removed while leaving the memory film 220U located on a side wall of the upper memory hole UMH. Therefore, an upper surface of the electrode body 60 is exposed. Accordingly, the configuration shown in FIG. 18 is obtained.

Next, as shown in FIG. 19, the electrode part 61U is formed on the electrode body 60. As a method of forming the electrode part 61U, a method of selectively growing silicon is applicable. For example, it is possible to provide the electrode part 61U formed of an epitaxial silicon layer by selectively growing the electrode body 60 formed of silicon containing impurities doped therein. Accordingly, the configuration shown in FIG. 19 is obtained.

Next, the upper array U2m is obtained by sequentially depositing the semiconductor body 210U and the core layer 230U on an inner wall of the memory film 220U in this order.

Finally, the obtained upper array U2m and the lower array L2m are subjected to annealing. Consequently, the impurities in the electrode parts 61L and 61U are thermally diffused to the semiconductor bodies 210L and 210U, respectively. Therefore, the impurity-diffusion regions 62L and 62U are formed.

Thereafter, although not shown in the drawings, an interlayer insulating film, a contact, and a wiring layer (bit line BL or the like) are formed. Furthermore, the semiconductor storage device 100 according to the embodiment is manufactured by replacing the sacrificial film 21d with the conductive layer 21. Note that, the CMOS circuit of the base body 1 may be formed on another substrate. In this case, the semiconductor storage device 100 may be formed by attaching a substrate including the multi-layered bodies L2 mm and U2 mm to the substrate including the CMOS circuit.

The semiconductor storage device 100 according to the first embodiment has been described above. The planar layout of the various elements constituting the semiconductor storage device 100 is not limited to the layout shown in FIGS. 3 and 4, and another layout may be adopted. For example, the number and the arrangement of the columnar parts CL disposed in one block BLK may be suitably modified.

In the configuration of the semiconductor storage device 100 according to the first embodiment, the electrode part 61 for generation of GIDL is provided at the joint part JT, and the impurity-diffusion region 62 is provided so as to extend from the electrode part 61 toward the semiconductor body 210 serving as a channel. Consequently, the electrode part 61 can function as the GIDL generation electrode that assists the GIDL current. Therefore, it is possible to obtain stable GIDL erasing characteristics. Moreover, conventionally, it has been required that a thickness of a channel (semiconductor body) be reduced in order to improve the cell characteristics. However, in the case in which the thickness of the channel is reduced, although the cell characteristics are improved, there is a problem in that an amount of the GIDL current decreases and therefore the GIDL erasing characteristics are degraded. In contrast, in the semiconductor storage device 100 according to the embodiment, the electrode part 61 for generation of GIDL is provided between the upper array and the lower array. For this reason, it is possible to stably supply the GIDL current, and as a result, it is possible to improve the electrical characteristics.

### Second Embodiment

Next, a second embodiment will be described.

The second embodiment is different from the first embodiment in that a conductive layer 90 electrically connected to the electrode body 60 is provided between the lower array L2m and the upper array U2m. The “conductive layer 90” is an example of a third conductive layer. Configurations other than the above that will be described in the second embodiment are the same as those of the first embodiment.

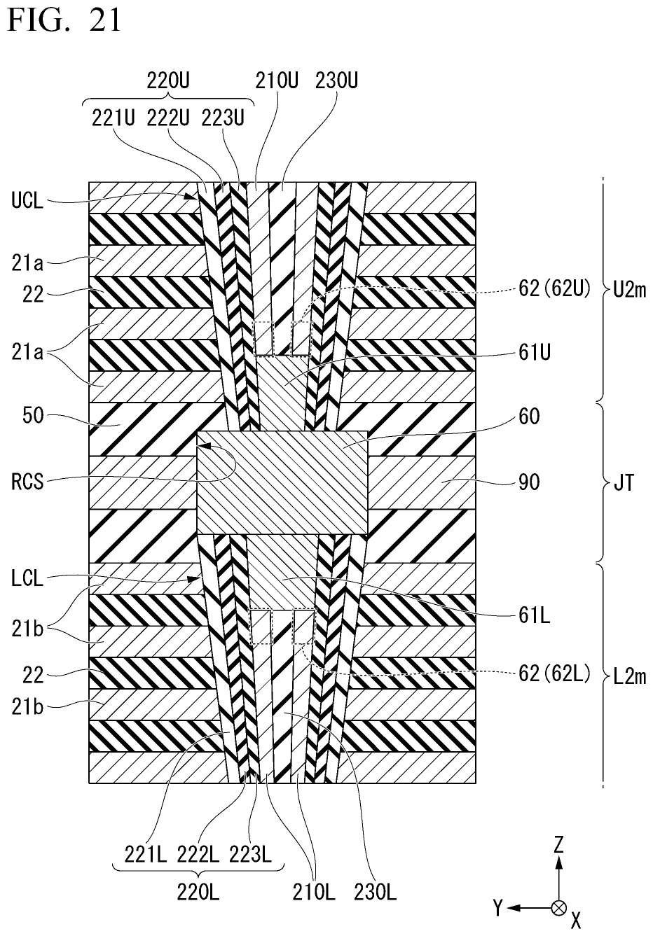

FIG. 21 is an enlarged cross-sectional view showing a region close to the electrode body 60 and the electrode parts 61U and 61L according to the second embodiment. That is, FIG. 21 is an enlarged cross-sectional view showing an example of a structure located close to the joint part JT the upper array U2m and the lower array L2m. The joint part JT is provided between the upper array U2m and the lower array L2m. Similar to the first embodiment, the interlayer 50, the electrode body 60, and the electrode parts 61U and 61L are provided in the joint part JT. Any one of the electrode parts 61U and 61L may be provided in the joint part JT.

The interlayer 50 is retracted in a direction (the X direction and the Y direction) away from a center of the columnar part CL. This means that the interlayer 50 is depressed from the upper array U2m and the lower array L2m in at least one of the X direction and the Y direction in the joint part JT. The interlayer 50 forms the recess RCS. Similar to the first embodiment, the recess RCS is filled with the electrode body 60.

The conductive layer 90 is a layered electroconductive film. The layered electroconductive film is formed so as to spread from a side surface of the electrode body 60 in the X direction and the Y direction in plan view when viewed from the Z direction (X-Y plane). The conductive layer 90 is connected to the electrode body 60. The conductive layer 90 is implanted into the inside of the interlayer 50. The surface of the conductive layer 90 (an upper surface and a lower surface) is electrically separated from the conductive layers 21a and 21b. The conductive layer 90 includes an electroconductive metal, for example, tungsten.

In the embodiment, the conductive layer 90 functions as a conductive layer that applies a voltage to the electrode parts 61L and 61U via the electrode body 60.

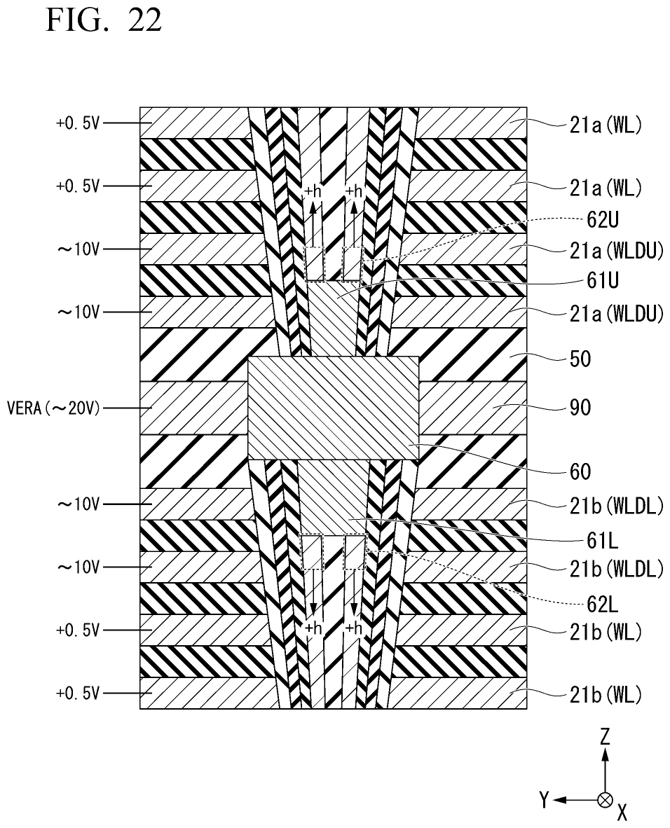

FIG. 22 is a cross-sectional view explaining an erase operation of a semiconductor storage device 100A according to the second embodiment. In an example shown in FIG. 22, a block erase operation will be described.

Also in the semiconductor storage device 100A according to the second embodiment, in a manner similar to the first embodiment, a reverse bias voltage is applied between the gate and the drain of at least one select transistor of the drain-side select transistor STD and the source-side select transistor STS. Furthermore, a reverse bias voltage is also applied between the electrode part 61 and the word line (conductive layer 21) located close to the electrode part 61. Consequently, the erase operation is carried out by generating GIDL. In the semiconductor storage device 100 according to the first embodiment, it is difficult to directly apply a voltage to the electrode part 61. For this reason, as the voltage Vera (approximately, 20V) is applied to the dummy word lines WLDU0 and WLDL0 adjacent to the electrode part 61, a predetermined voltage (approximately, 10V) is applied to each of the plurality of the electrode parts 61 due to capacitor coupling. On the other hand, in the case of the semiconductor storage device 100A according to the second embodiment, the voltage Vera (approximately, 20V) is directly applied to the conductive layer 90 connected to the electrode body 60, and therefore a predetermined voltage (approximately, 10V) is applied to each of the plurality of the electrode parts 61. Accordingly, the erase operation can be further stably executed. Note that, also in the case of the semiconductor storage device 100A according to the second embodiment, in order to prevent each constituent element of the columnar part CL from being degraded, it is preferable to apply a midpoint potential (for example, approximately, 10V) to a part of the conductive layer 21 located at the position close to the conductive layer 90. Here, the midpoint potential is the middle value between the voltage Vera to be applied to the dummy word lines WLDL and WLDU and the voltage to be applied to the word line WL. However, the number of the dummy word lines WLDL and WLDU are not limited.

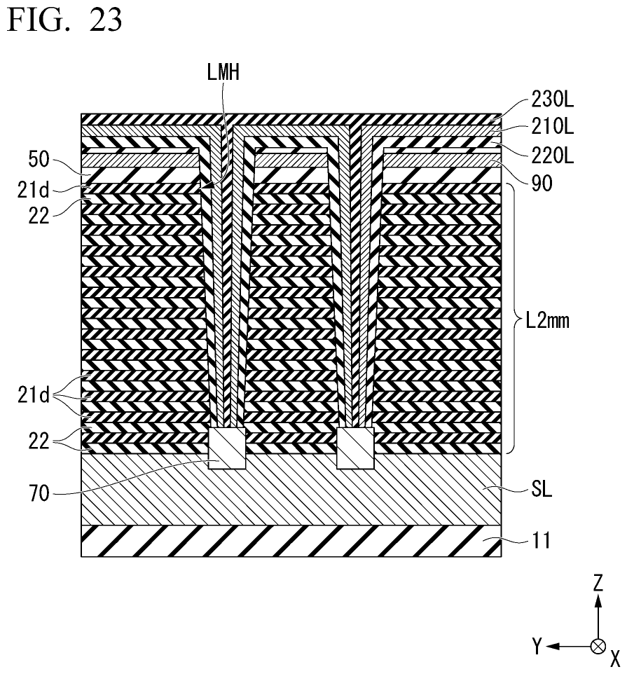

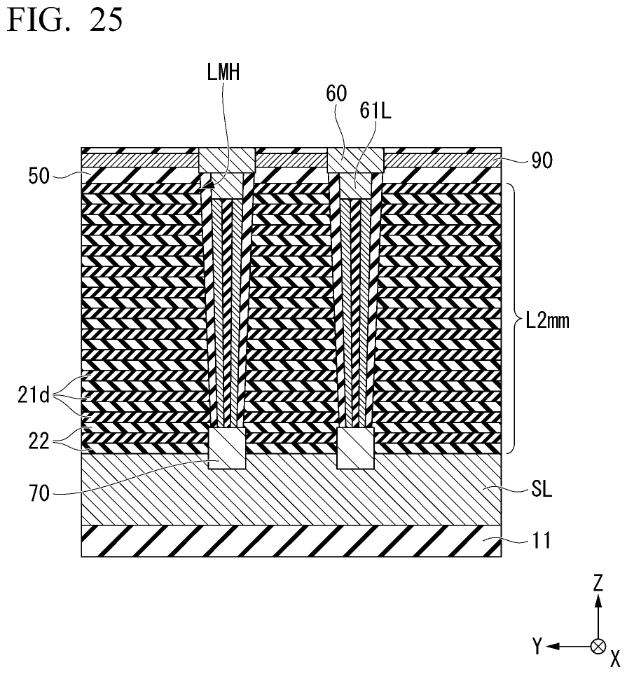

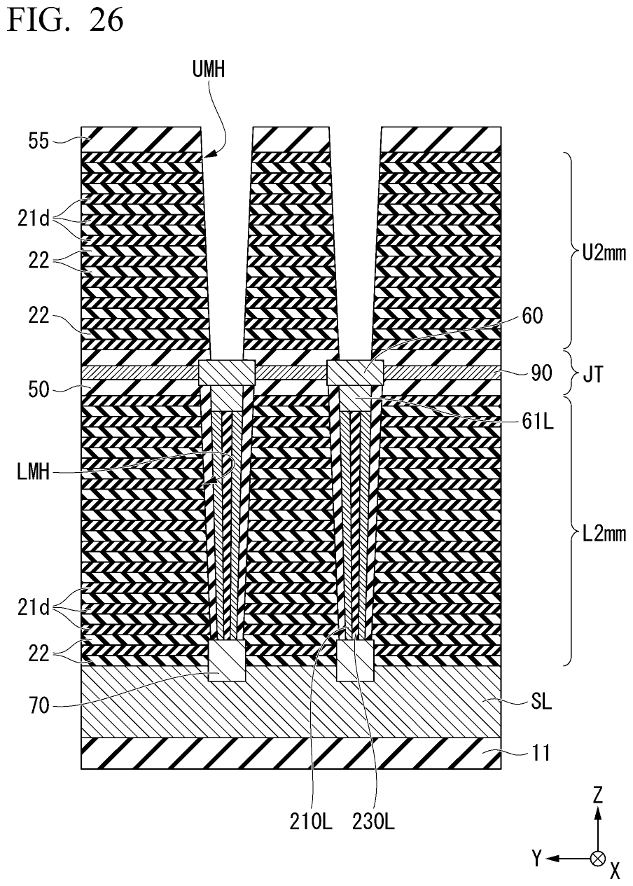

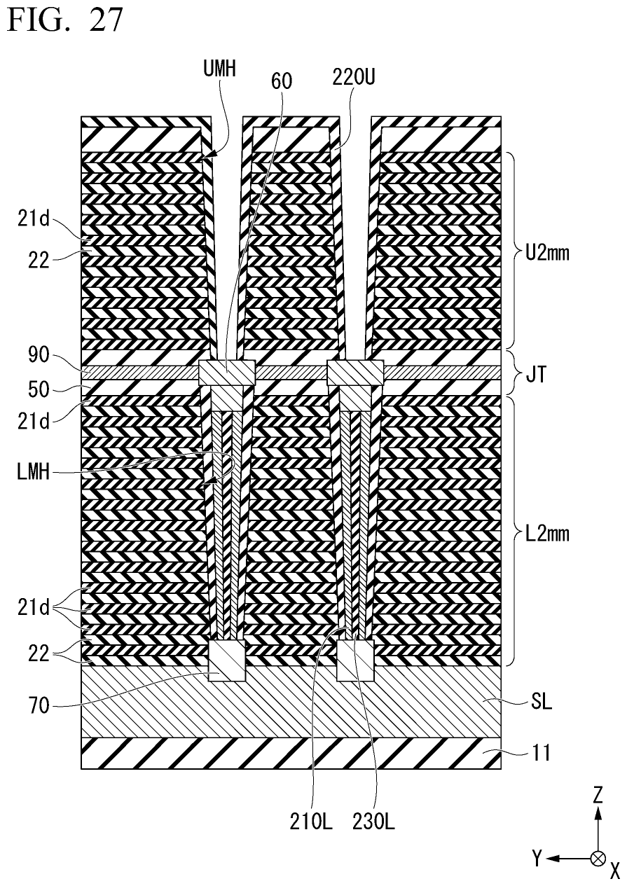

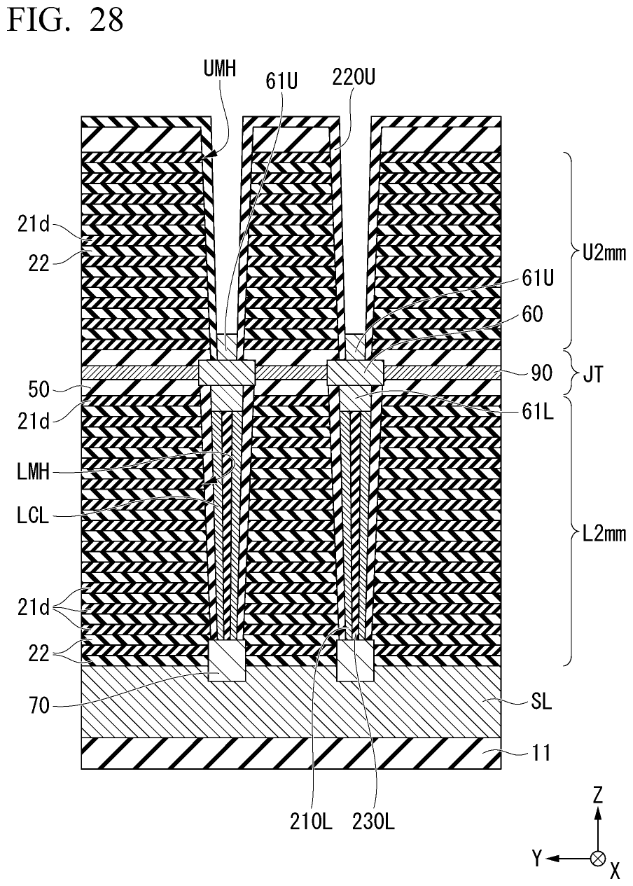

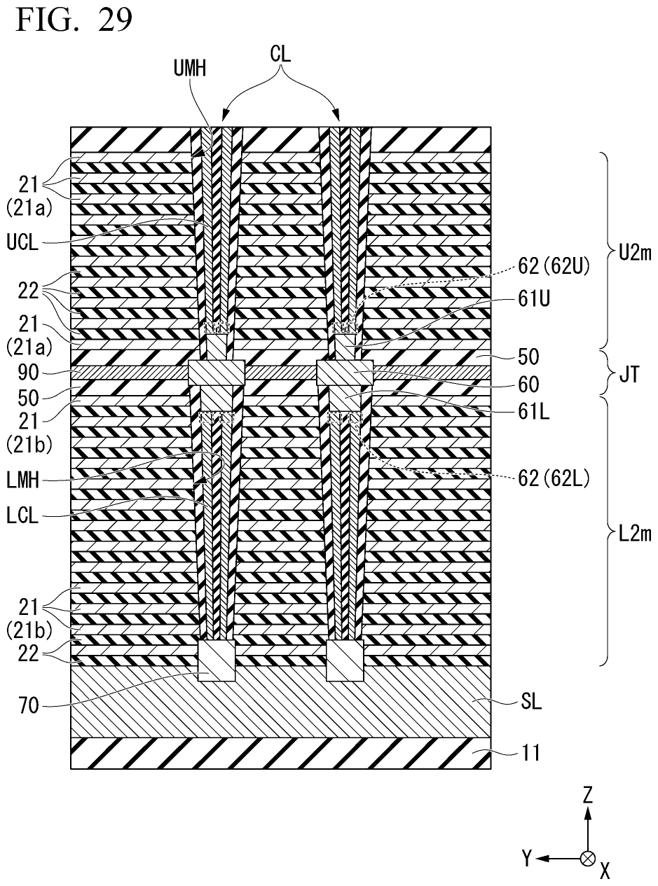

Next, a method of manufacturing the semiconductor storage device 100A according to the second embodiment will be described. FIG. 23 to FIG. 29 are cross-sectional views explaining a method of manufacturing the semiconductor storage device 100A according to the second embodiment.

First of all, as shown in FIG. 23, similar to the first embodiment, the plurality of the sacrificial films 21d and the plurality of the insulating films 22 are alternately stacked in layers above the base body 1 in the Z direction. Consequently, the multi-layered body L2 mm including the sacrificial films 21d and the insulating films 22 is formed on the region of the lower array L2m.

Next, after a part of the interlayer 50 is formed on the multi-layered body L2 mm, the conductive layer 90 is formed on the interlayer 50. The conductive layer 90 includes an electroconductive metal, for example, tungsten. Next, the remaining portion of the interlayer 50 is formed on the conductive layer 90.

Next, similar to the first embodiment, the lower memory hole LMH is provided in the interlayer 50, the conductive layer 90, and the multi-layered body L2 mm so as to extend in the Z direction by use of a lithography technique, an RIE method, or the like. Therefore, the lower memory hole LMH that penetrates through the multi-layered body L2 mm is formed.

Next, the epitaxial silicon layer 70 is formed on the bottom portion of the lower memory hole LMH. Furthermore, the memory film 220L and the semiconductor body 210L are formed on the inner wall of the lower memory hole LMH. Next, the memory film 220L and the semiconductor body 210L located on the bottom portion of the lower memory hole LMH are removed while leaving the memory film 220L and the semiconductor body 210L located on the side wall of the lower memory hole LMH.

Next, the core layer 230L is formed in the lower memory hole LMH and on an upper surface of the semiconductor body 210L. The core layer 230L is formed such that the inside space of the lower memory hole LMH is filled with the core layer 230L. Accordingly, the configuration shown in FIG. 23 is obtained.

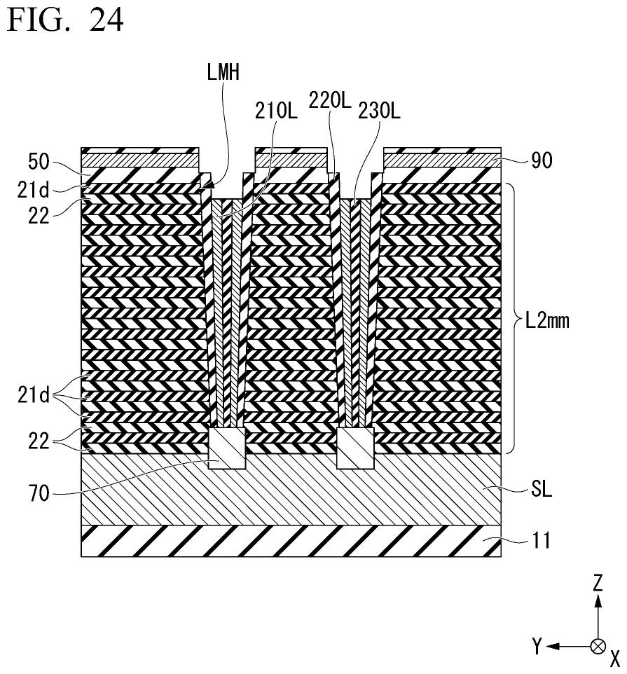

Subsequently, the same methods as those of the first embodiment are carried out as shown in FIGS. 24 to 29, and therefore it is possible to manufacture the semiconductor storage device 100A according to the second embodiment.

Also in the above-described configuration according to the second embodiment, similar to the first embodiment, the electrode part 61 can function as the GIDL generation electrode that assists the GIDL current. Therefore, it is possible to obtain stable GIDL erasing characteristics. As a result, it is possible to improve the electrical characteristics of the semiconductor storage device 100A. Furthermore, in the second embodiment, the conductive layer 90 adjacent to the electrode body 60 is provided. Accordingly, it is possible to directly apply the voltage Vera to the conductive layer 90. As a result, a further stabilized erase operation is achieved.

Although some embodiments have been described above, the embodiments are not limited to the above-mentioned examples. For example, the memory film may be a ferroelectric film. The ferroelectric film is included in a FeFET (Ferroelectric FET) memory that stores data due to a polarization direction. The ferroelectric film is formed of, for example, hafnium oxide.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device, comprising:
a first multi-layered body including a plurality of first conductive layers, the first conductive layers being stacked in layers in a first direction, the first conductive layers being electrically isolated from each other,
a second multi-layered body above the first multi-layered body, the second multi-layered body including a plurality of second conductive layers, the second conductive layers being stacked in layers in the first direction, the second conductive layers being electrically isolated from each other;
a first columnar part in the first multi-layered body, the first columnar part extending in the first direction, the first columnar part including a first charge storage film and a first semiconductor layer, the first columnar part having an upper end;
a second columnar part in the second multi-layered body, the second columnar part extending in the first direction, the second columnar part including a second charge storage film and a second semiconductor layer, the second columnar part having a lower end;
an electrode part inside at least one of the upper end of the first columnar part and the lower end of the second columnar part, the electrode part having an end surface; and
an impurity-diffusion region protruding from the end surface of the electrode part toward an inside of the first semiconductor layer in the first direction.

2. The semiconductor storage device according to claim 1, wherein
the electrode part inside the upper end of the first columnar part is a first electrode part,
the electrode part inside the lower end of the second columnar part is a second electrode part, and
both the first electrode part and the second electrode part are in the semiconductor storage device.

3. The semiconductor storage device according to claim 2, further comprising
an electrode body electrically connecting the first electrode part and the second electrode part.

4. The semiconductor storage device according to claim 2, wherein
a position of the lower end of the first electrode part is lower than a position of a first conductive layer located at an uppermost position of the plurality of the first conductive layers, and
a position of the upper end of the second electrode part is above a position of a second conductive layer located at a lowermost portion of the plurality of the second conductive layers.

5. The semiconductor storage device according to claim 2, wherein
a length of the first electrode part in a second direction crossing the first direction is substantially the same as a length of the first semiconductor layer in the second direction, and
a length of the second electrode part in the second direction is substantially the same as a length of the second semiconductor layer in the second direction.

6. The semiconductor storage device according to claim 3, wherein
a material used to form the electrode body, a material used to form the first electrode part, and a material used to form the second electrode part are the same as each other.

7. The semiconductor storage device according to claim 3, further comprising
a third conductive layer electrically isolating the plurality of the first conductive layers and the plurality of the second conductive layers from each other between the first multi-layered body and the second multi-layered body, the third conductive layer being electrically connected to the electrode body.
